(19) United States
(12) Patent Application Publication
(10) Pub. No.: US 2025/0255072 A1
(43) Pub. Date: Aug. 7, 2025

(54) DISPLAY DEVICE AND ELECTRONIC DEVICE INCLUDING THE SAME

(71) Applicant: Samsung Display Co., LTD., Yongin-si (KR)

(72) Inventor: JUNHYUN PARK, Yongin-si (KR)

(21) Appl. No.: 19/039,104

(22) Filed: Jan. 28, 2025

(30) Foreign Application Priority Data
Feb. 6, 2024 (KR) 10-2024-0018197
Oct. 22, 2024 (KR) 10-2024-0145231

(51) Int. Cl. H10H 29/49; H10H 29/24; H10H 29/30; H10H 29/34; H10H 29/39

(52) U.S. Cl. CPC H10H 29/49; H10H 29/24; H10H 29/345; H10H 29/352; H10H 29/39

(57) ABSTRACT

A display device includes a display panel including a circuit layer and a light-emitting element layer. The circuit layer includes a transistor, a connection electrode electrically connecting the transistor and the light-emitting element layer, a data line, and an insulating layer provided with a contact hole defined therethrough. The light-emitting element layer includes a first electrode electrically connected to the connection electrode through the contact hole, a light-emitting layer disposed on the first electrode, and a second electrode disposed on the light-emitting layer. The first electrode includes a first portion, a second portion extending from the first portion to a first direction, a third portion extending from the first portion to the first direction, and a fourth portion protruded from one of the first, second, and third portions.

This application claims priority to Korean Patent Application No. 10-2024-0018197, filed on Feb. 6, 2024 and Korean Patent Application No. 10-2024-0145231, field on Oct. 22, 2024, and all the benefits accruing therefrom under 35 U.S.C. § 119, the content of which in its entirety is herein incorporated by reference.

### BACKGROUND

### 1. Field

The disclosure relates to a display device with improved display quality.

### 2. Description of Related Art

Various display devices applied to multimedia devices, such as televisions, mobile phones, tablet computers, navigation devices, and game devices, are being developed.

As the fields of applications for these display devices have diversified, the types of display panels used to display images on these display devices are also diversifying.

The display panels include a light-emitting type display panel, and the light-emitting type display panel includes an organic light-emitting display panel or a quantum dot light-emitting display panel.

### SUMMARY

The disclosure provides a display device with improved display quality.

An embodiment of the inventive concept provides a display device including a display panel including a circuit layer and a light-emitting element layer disposed on the circuit layer. The circuit layer includes a base layer, a transistor disposed on the base layer, a connection electrode electrically connecting the transistor and the light-emitting element layer, a data line disposed on the transistor, and an insulating layer disposed on the connection electrode and provided with a contact hole defined therethrough. The light-emitting element layer includes a first electrode disposed on the insulating layer and electrically connected to the connection electrode through the contact hole, a light-emitting layer disposed on the first electrode, and a second electrode disposed on the light-emitting layer. The first electrode includes a first portion, a second portion extending from the first portion to a first direction, a third portion extending from the first portion to the first direction, and a fourth portion protruded from one of the first, second, and third portions. The second portion and the third portion are spaced apart from each other and face each other in a second direction.

In an embodiment, the first portion, the second portion, the third portion, and the fourth portion are provided integrally with each other.

In an embodiment, the data line is disposed between the second portion and the third portion and does not overlap the second and third portions in a plan view.

In an embodiment, the contact hole overlaps the fourth portion in the plan view.

In an embodiment, the light-emitting layer does not overlap the contact hole in the plan view.

In an embodiment, the data line overlaps only the first portion in the plan view.

In an embodiment, the data line is disposed in the same layer as the connection electrode.

In an embodiment, the light-emitting layer includes a first light-emitting portion having a shape corresponding to a shape of the first portion, a second light-emitting portion having a shape corresponding to a shape of the second portion, and a third light-emitting portion having a shape corresponding to a shape of the third portion.

In an embodiment, the first light-emitting portion, the second light-emitting portion, and the third light-emitting portion are provided integrally with each other.

In an embodiment, the light-emitting layer emits a blue light.

An embodiment of the inventive concept provides a display device including a display panel including a circuit layer and a light-emitting element layer disposed on the circuit layer. The circuit layer includes a transistor, a connection electrode electrically connecting the transistor and the light-emitting element layer, and an insulating layer disposed on the connection electrode and provided with a contact hole defined therethrough. The light-emitting element layer includes a first electrode disposed on the insulating layer, a light-emitting layer disposed on the first electrode, and a second electrode disposed on the light-emitting layer. The light-emitting layer includes a first light-emitting portion and a second light-emitting portion spaced apart from the first light-emitting portion by a first width, and the first electrode includes a first portion, a second portion spaced apart from the first portion by a second width smaller than the first width, a connection portion electrically connecting the first portion and the second portion, and a protruding portion protruded from one of the first portion, the second portion, and the connection portion.

In an embodiment, the first electrode further includes a third portion spaced apart from the second portion in a first direction, and the second portion is spaced apart from the first portion in the first direction.

In an embodiment, the first portion, the second portion, the third portion, the connection portion, and the protruding portion are provided integrally with each other.

In an embodiment, the light-emitting layer emits a blue light.

In an embodiment, the contact hole overlaps the protruding portion in a plan view.

In an embodiment, the light-emitting layer does not overlap the contact hole in the plan view.

In an embodiment, the light-emitting layer further includes a third light-emitting portion spaced apart from the second light-emitting portion by the first width.

An embodiment of the inventive concept provides a display device including a display panel including a circuit layer and a light-emitting element layer disposed on the circuit layer. The circuit layer includes a transistor, a connection electrode electrically connecting the transistor and the light-emitting element layer, and an insulating layer disposed on the connection electrode and provided with a contact hole defined therethrough. The light-emitting element layer includes a first electrode disposed on the insulating layer, a light-emitting layer disposed on the first electrode, and a second electrode disposed on the light-emitting layer. The light-emitting layer includes a first light-emitting portion and a second light-emitting portion spaced apart from the first light-emitting portion by a first width, and the first electrode includes a first portion, a second portion spaced apart from the first portion by a second width greater than the first width, and a connection portion electrically connecting the first portion and the second portion.

In an embodiment, the first electrode further includes a third portion spaced apart from the second portion in a first direction, and the second portion is spaced apart from the first portion in the first direction.

In an embodiment, the first portion, the second portion, the third portion, and the connection portion are provided integrally with each other.

In an embodiment, the contact hole overlaps the connection portion in the plan view.

In an embodiment, the first electrode further includes a third portion spaced apart from the first portion in the first direction and a fourth portion spaced apart from the second portion in a second direction intersecting the first direction, and the second portion is spaced apart from the first portion in the second direction.

In an embodiment, the first portion, the second portion, the third portion, the fourth portion, and the connection portion are provided integrally with each other.

In an embodiment, the light-emitting layer does not overlap the contact hole in the plan view.

In an embodiment, the contact hole overlaps the second portion and does not overlap the first portion in the plan view.

According to the above, a third data line is disposed between the second portion and the third portion of the first electrode. Since the third data line does not overlap the second portion and the third portion in the plan view, a parasitic capacitance generated between the third data line and the second and third portions is reduced. Accordingly, the increase in the load of a data signal applied to the third data line, which is caused by the parasitic capacitance, is prevented, and the third data line is prevented from being insufficiently charged. As a result, the reliability of the display device is improved.

According to the above, since there is a gap between the second portion and the third portion, an outgas generated during processes is smoothly discharged. Thus, a pixel shrinkage phenomenon is reduced, and the lifespan of a third light-emitting layer increases. Accordingly, the reliability of the display device is improved.

According to the above, the third light-emitting layer does not overlap a third contact hole in the plan view. Thus, when the third contact hole is defined, insulating layers disposed under the third light-emitting layer are stacked flat. As a result, the light reflectance of the third light-emitting layer is maintained at a constant level and the color deviation phenomenon is prevented. Accordingly, the display quality of the display device is improved.

### BRIEF DESCRIPTION OF THE DRAWINGS

The above and other advantages of the disclosure will become readily apparent by reference to the following detailed description when considered in conjunction with the accompanying drawings, in which:

FIG. 1 is a perspective view of an embodiment of a display device according to the disclosure;

FIG. 2 is an exploded perspective view of an embodiment of a display device according to the disclosure;

FIG. 3 is a block diagram of an embodiment of a display device according to the disclosure;

FIG. 4 is a cross-sectional view of an embodiment of a display device according to the disclosure;

FIG. 5 is an equivalent circuit diagram of an embodiment of a pixel according to the disclosure;

FIG. 6 is a plan view of a portion of an embodiment of a display device according to the disclosure;

FIG. 7 is a cross-sectional view taken along line I-I′ of FIG. 6 according to the disclosure;

FIG. 8 is a plan view of an embodiment of a portion of a display device according to the disclosure;

FIG. 9 is a plan view of an embodiment of a portion of a display device according to the disclosure;

FIG. 10 is a plan view of an embodiment of a portion of a display device according to the disclosure; and

FIG. 11 is a plan view of an embodiment of a portion of a display device according to the disclosure;

FIG. 12 is a block diagram illustrating an embodiment of an electronic device; and

FIG. 13 is a view illustrating an embodiment of the electronic device of FIG. 12 implemented as a smartphone.

### DETAILED DESCRIPTION

In the disclosure, it will be understood that when an element (or area, layer, or portion) is referred to as being “on”, “connected to” or “coupled to” another element or layer, it may be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the drawing figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to accompanying drawings.

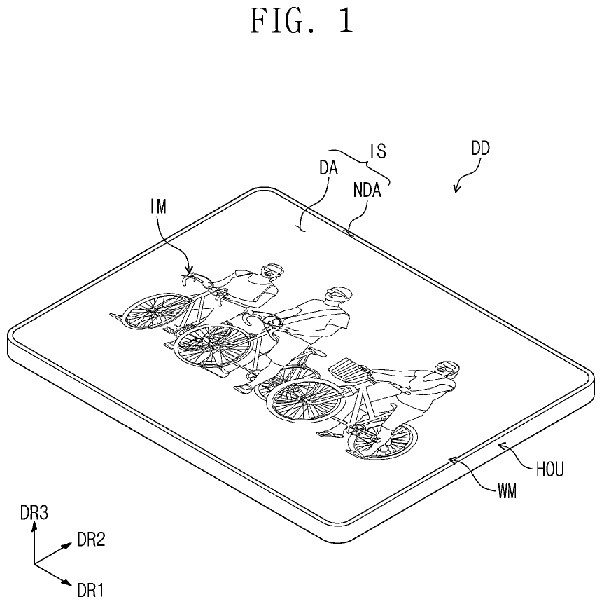

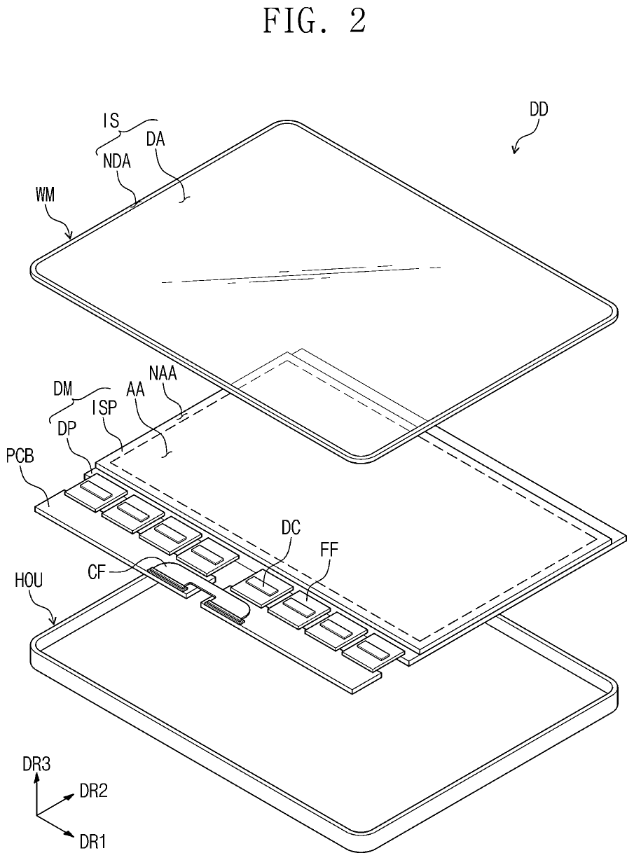

FIG. 1 is a perspective view of an embodiment of a display device DD according to the disclosure, and FIG. 2 is an exploded perspective view of an embodiment of the display device DD according to the disclosure.

Referring to FIGS. 1 and 2, the display device DD may be a device activated in response to electrical signals. The display device DD may be applied to a large-sized display device, such as a television set or a monitor, or may be applied to a relatively small and medium-sized display device, such as a mobile phone, a tablet computer, a notebook computer, a car navigation unit, a game unit, etc. However, these are merely illustrative embodiments, and the display device DD may be applied to other display devices as long as they do not depart from the concept of the disclosure. The display device DD may have a quadrangular shape, e.g., rectangular shape defined by long sides extending in a first direction DR1 and short sides extending in a second direction DR2 intersecting the first direction DR1. However, the shape of the display device DD should not be limited to the quadrangular shape, e.g., rectangular shape, and the display device DD may have a variety of shapes. The display device DD may display an image IM toward a third direction DR3 through a display surface IS that is substantially parallel to each of the first direction DR1 and the second direction DR2. The display surface IS through which the image IM is displayed may correspond to a front surface of the display device DD.

In the illustrated embodiment, front (or upper) and rear (or lower) surfaces of each member may be defined with respect to the direction in which the image IM is displayed. The front and rear surfaces may be opposite to each other in the third direction DR3, and a normal line direction of each of the front and rear surfaces may be substantially parallel to the third direction DR3.

A separation distance in the third direction DR3 between the front surface and the rear surface may correspond to a thickness in the third direction DR3 of the display device DD. Directions indicated by the first, second, and third directions DR1, DR2, and DR3 may be relative to each other and may be changed to other directions.

The display device DD may sense an external input applied thereto from the outside. The external input may include inputs of various forms provided from the outside of the display device DD. The display device DD may sense an external input generated by a user and applied thereto. The external input by the user may include one of various forms of external inputs, such as a portion of the user's body, light, heat, gaze, or pressure, or any combinations thereof. In addition, the display device DD may sense the external input applied to a side surface or a rear surface thereof by the user according to a structure thereof, however, it should not be limited thereto or thereby. In an embodiment, the external input may include inputs generated by an input device, e.g., a stylus pen, an active pen, a touch pen, an electronic pen, an e-pen, or the like.

The display surface IS of the display device DD may include a display area DA and a non-display area NDA. The display area DA may be an area in which the image IM is displayed. The user may view the image IM through the display area DA. In the illustrated embodiment, the display area DA may have a quadrangular shape with rounded vertices, however, this is merely one of embodiments. The display area DA may have a variety of shapes and should not be particularly limited.

The non-display area NDA may be defined next (adjacent) to the display area DA. The non-display area NDA may have a predetermined color. The non-display area NDA may surround the display area DA. Accordingly, the display area DA may have a shape substantially defined by the non-display area NDA, however, this is merely one of embodiments. In an embodiment, the non-display area NDA may be disposed next (adjacent) to only one side of the display area DA or may be omitted. The display device DD may include various embodiments and should not be particularly limited.

Referring to FIG. 2, the display device DD may include a display module DM and a window WM disposed on the display module DM. The display module DM may include a display panel DP and an input sensing layer ISP.

The display panel DP may be a light-emitting type display panel. In an embodiment, the display panel DP may be an organic light-emitting display panel, an inorganic light-emitting display panel, or a quantum dot light-emitting display panel. A light-emitting layer of the organic light-emitting display panel may include an organic light-emitting material. A light-emitting layer of the inorganic light-emitting display panel may include an inorganic light-emitting material. A light-emitting layer of the quantum dot light-emitting display panel may include a quantum dot or a quantum rod.

The display panel DP may output the image IM, and the output image IM may be displayed through the display surface IS.

The input sensing layer ISP may be disposed on the display panel DP and may sense the external input. The input sensing layer ISP may be disposed directly on the display panel DP. In the illustrated embodiment, the input sensing layer ISP may be formed on the display panel DP through successive processes. That is, when the input sensing layer ISP is disposed directly on the display panel DP, an inner adhesive film may not be disposed between the input sensing layer ISP and the display panel DP. However, in an embodiment, the inner adhesive film may be disposed between the input sensing layer ISP and the display panel DP. In this case, the input sensing layer ISP may not be manufactured through the successive processes with the display panel DP, and the input sensing layer ISP may be fixed to an upper surface of the display panel DP by the inner adhesive film after being manufactured through a separate process.

The window WM may include a transparent material through which the image IM transmits. In an embodiment, the window WM may include glass, sapphire, or plastic, for example. The window WM is shown as a single layer, however, it should not be limited thereto or thereby. The window WM may include a plurality of layers.

Although not shown in drawing figures, the non-display area NDA of the display device DD may be obtained by printing a material having the predetermined color on an area of the window WM. In an embodiment, the window WM may include a light-blocking pattern to define the non-display area NDA. The light-blocking pattern may be a colored organic layer and may be formed by a coating method.

The window WM may be coupled to the display module DM by an adhesive film. In an embodiment, the adhesive film may include an optically clear adhesive film (“OCA”). However, the adhesive film should not be limited thereto or thereby, and the adhesive film may include a conventional adhesive. In an embodiment, the adhesive film may include an optically clear resin (“OCR”) or a pressure sensitive adhesive film (“PSA”), for example.

An anti-reflective layer may be further disposed between the window WM and the display module DM. The anti-reflective layer may reduce a reflectance with respect to an external light incident thereto from the above of the window WM. The anti-reflective layer according to the disclosure may include a retarder and a polarizer. The retarder may be a film type or liquid crystal coating type. The polarizer may also be a film type or liquid crystal coating type. The film type polarizer and retarder may include a stretching type synthetic resin film, and the liquid crystal coating type polarizer and retarder may include liquid crystals aligned in a predetermined alignment. The retarder and the polarizer may be implemented as one polarizing film.

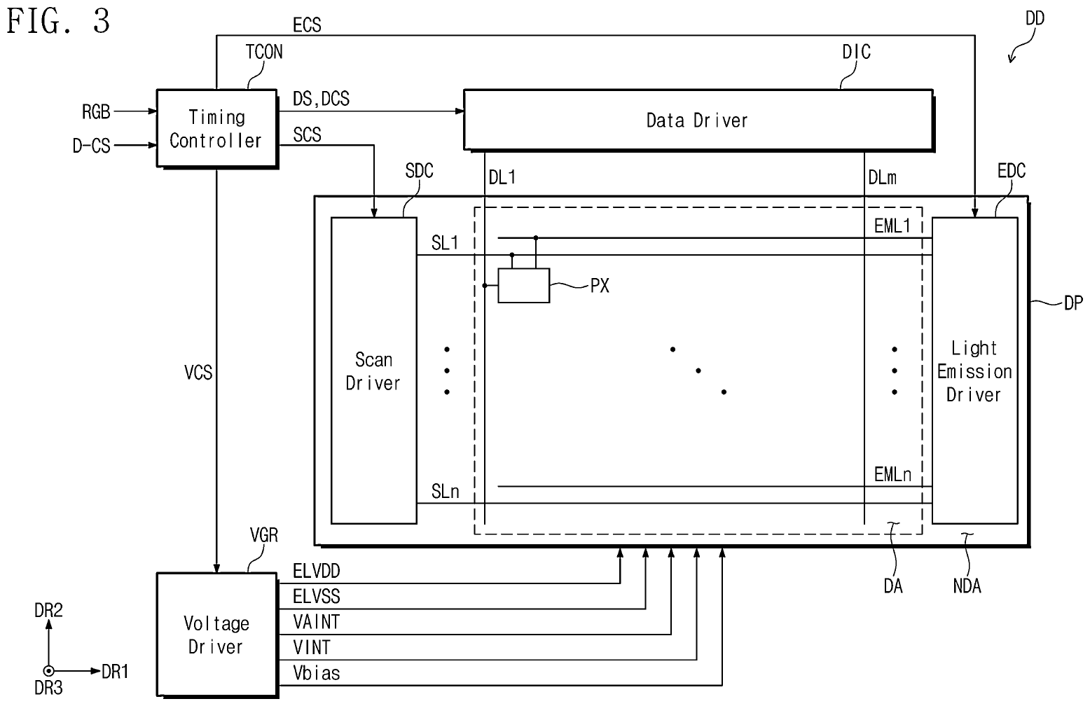

In an embodiment, the anti-reflective layer may include color filters. An arrangement of the color filters may be determined by taking into account colors of lights generated by pixels PX (refer to FIG. 3) included in the display panel DP. In this case, the anti-reflective layer may further include a light-blocking pattern disposed between the color filters.

The display module DM may display the image IM in response to electrical signals and may transmit/receive information on the external input. The display module DM may include an effective area AA and a non-effective area NAA, which are defined therein. The effective area AA may be defined as an area through which the image IM provided from the display panel DP exits, i.e., an area through which the image IM is displayed. In addition, the effective area AA may be defined as an area where the input sensing layer ISP senses the external input applied thereto from the outside. In an embodiment, the effective area AA of the display module DM may correspond to or overlap at least a portion of the display area DA.

The non-effective area NAA may be defined next (adjacent) to the effective area AA. The non-effective area NAA may be an area where the image IM is not displayed. In an embodiment, the non-effective area NAA may surround the effective area AA, for example. However, this is merely one of embodiments, and the non-effective area NAA may be defined in various shapes and should not be particularly limited. According to the embodiment, the non-effective area NAA of the display module DM may correspond to or overlap at least a portion of the non-display area NDA.

The display device DD may further include a plurality of flexible films FF. A driving chip DC may be disposed (e.g., mounted) on each of the flexible films FF. In an embodiment, the driving chip DC may be provided in plural, a data driver DIC (refer to FIG. 3) may be implemented by the driving chips DC, and the driving chips DC may be disposed (e.g., mounted) on the flexible films FF, respectively.

The display device DD may further include at least one circuit board PCB coupled with the flexible films FF. FIG. 2 shows a structure in which the display device DD includes two circuit boards PCB, however, the number of the circuit boards PCB should not be limited to two. Among the circuit boards PCB, two circuit boards PCB next (adjacent) to each other may be electrically connected to each other by a connection film CF. In addition, at least one of the circuit boards PCB may be electrically connected to a main board. A timing controller TCON (refer to FIG. 3) may be disposed (e.g., mounted) on at least one of the circuit boards PCB.

FIG. 2 shows a structure in which the driving chips DC are respectively disposed (e.g., mounted) on the flexible films FF, however, the disclosure should not be limited thereto or thereby. In an embodiment, the driving chips DC may be directly disposed (e.g., mounted) on the display panel DP. In this case, portions of the display panel DP on which the driving chips DC are disposed (e.g., mounted) may be bent and may be disposed on the rear surface of the display device DD.

The input sensing layer ISP may be electrically connected to the circuit board PCB via the flexible films FF, however, the disclosure should not be limited thereto or thereby. That is, the display module DM may further include a separate flexible film to electrically connect the input sensing layer ISP to the circuit board PCB.

The display device DD may further include a housing HOU that accommodates the display module DM. The window WM may be coupled with the housing HOU to define an exterior of the display device DD. The housing HOU may absorb impacts applied thereto from the outside and may prevent foreign substances/moisture from entering the display module DM to protect components accommodated in the housing HOU. In an embodiment, the housing HOU may be obtained by assembling a plurality of accommodating members.

The display device DD may further include an electronic module that includes various functional modules to operate the display module DM, a power supply module, e.g., a battery, that supplies a power source desired for an overall operation of the display device DD, and a bracket that is coupled with the display module DM and/or the housing HOU to divide an inner space of the display device DD.

FIG. 3 is a block diagram of the display device DD according to the disclosure.

Referring to FIG. 3, the display device DD may include the display panel DP, the timing controller TCON, the data driver DIC, and a voltage generator VGR.

The timing controller TCON may receive input data RGB and control signals D-CS from an external controller (not shown). In an embodiment, the external controller (not shown) may be a graphics processing unit (“GPU”). The control signals D-CS may include various signals. In an embodiment, the control signals D-CS may include an input vertical synchronization signal, an input horizontal synchronization signal, a main clock, and a data enable signal.

The timing controller TCON may convert a data format of the input data RGB to a data format appropriate to an interface between the data driver DIC and the timing controller TCON and may generate image data DS.

The timing controller TCON may generate a scan control signal SCS, a data control signal DCS, and a light emission control signal ECS, and a voltage control signal VCS based on the control signals D-CS.

The data driver DIC may output grayscale voltages in response to the data control signal DCS and the image data DS from the timing controller TCON to drive a plurality of data lines DL1 to DLm where m is a natural number. The data driver DIC may be implemented in an integrated circuit and may be directly disposed (e.g., mounted) on a predetermined portion of the display panel DP or may be electrically connected to the display panel DP after being disposed (e.g., mounted) on a separate printed circuit board by a chip-on-film method, but it should not be particularly limited. In an embodiment, the data driver DIC may be formed through the same process as a circuit layer of the display panel DP.

The display panel DP may include the display area DA and the non-display area NDA. The pixels PX may be arranged in the display area DA, and a scan driver SDC and a light emission driver EDC may be disposed in the non-display area NDA.

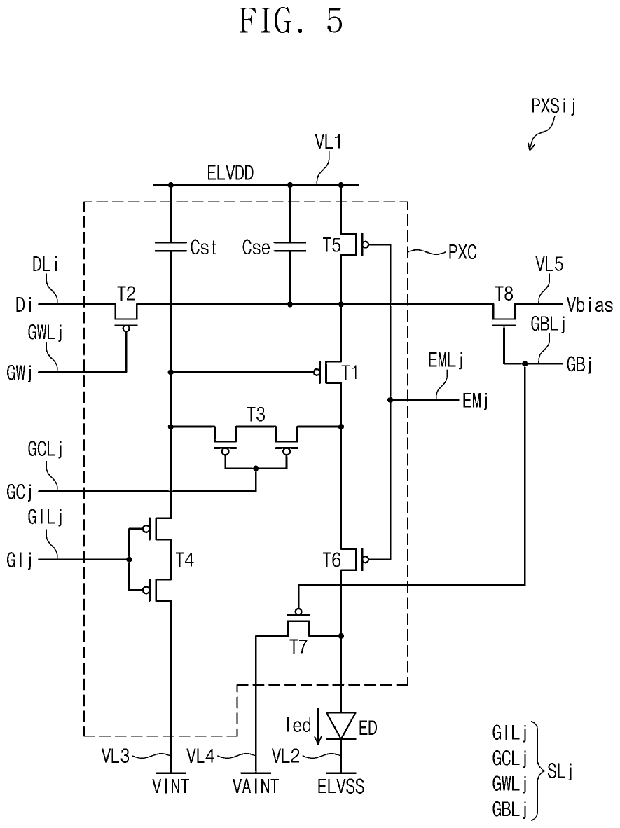

The display panel DP may include a plurality of scan lines SL1 to SLn, where n is a natural number, the data lines DL1 to DLm, a plurality of light emission control lines EML1 to EMLn, the pixels PX, the scan driver SDC, and the light emission driver EDC. Each of the pixels PX may be connected to a corresponding data line among the data lines DL1 to DLm and a corresponding scan line among the scan lines SL1 to SLn. The scan lines SL1 to SLn may include a plurality of first scan lines, a plurality of second scan lines, and a plurality of third scan lines. The scan lines SL1 to SLn will be described in detail with reference to FIG. 5. Each of the pixels PX may be connected to a corresponding light emission control line among the light emission control lines EML1 to EMLn.

The scan driver SDC may be disposed at a first side of the display panel DP. The scan lines SL1 to SLn may extend from the scan driver SDC to the first direction DR1.

The light emission driver EDC may be disposed at a second side of the display panel DP. The light emission control lines EML1 to EMLn may extend from the light emission driver EDC to a direction opposite to the first direction DR1.

The scan lines SL1 to SLn may be arranged spaced apart from each other in the second direction DR2, and the light emission control lines EML1 to EMLn may be arranged spaced apart from each other in the second direction DR2.

The data lines DL1 to DLm may extend from the data driver DIC to a direction opposite to the second direction DR2 and may be arranged spaced apart from each other in the first direction DR1.

As shown in FIG. 3, the scan driver SDC and the light emission driver EDC may be arranged to face each other with the pixels PX interposed therebetween, however, the disclosure should not be limited thereto or thereby. In an embodiment, the scan driver SDC and the light emission driver EDC may be disposed next (adjacent) to each other at either the first side or the second side of the display panel DP. In an embodiment, the scan driver SDC and the light emission driver EDC may be implemented in a single circuit.

The pixels PX may be electrically connected to the scan lines SL1 to SLn, the light emission control lines EML1 to EMLn, and the data lines DL1 to DLm.

Each of the pixels PX may receive a driving voltage ELVDD, a power supply voltage ELVSS, an initialization voltage VINT, an anode initialization voltage VAINT, and a bias voltage Vbias from the voltage generator VGR.

The scan driver SDC may receive the scan control signal SCS from the timing controller TCON. The scan driver SDC may output scan signals to the scan lines SL1 to SLn in response to the scan control signal SCS.

The light emission driver EDC may receive the light emission control signal ECS from the timing controller TCON. The light emission driver EDC may output light emission signals to the light emission control lines EML1 to EMLn in response to the light emission control signal ECS.

The voltage generator VGR may receive the voltage control signal VCS from the timing controller TCON. The voltage generator VGR may generate voltages desired for operation of the display panel DP in response to the voltage control signal VCS. In the illustrated embodiment, the voltage generator VGR may generate the driving voltage ELVDD, the power supply voltage ELVSS, the initialization voltage VINT, the anode initialization voltage VAINT, and the bias voltage Vbias.

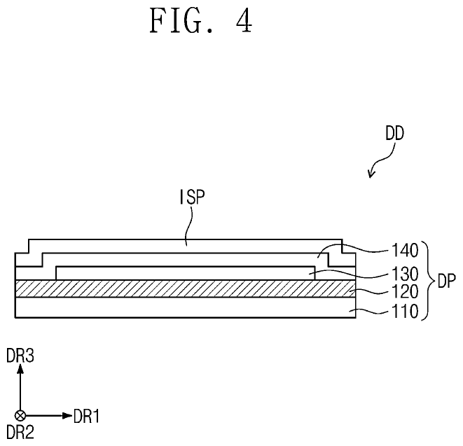

FIG. 4 is a cross-sectional view of an embodiment of the display device DD according to the disclosure.

Referring to FIG. 4, the display device DD may include the display panel DP and the input sensing layer ISP. The display panel DP may include a base layer 110, a circuit layer 120, a light-emitting element layer 130, and an encapsulation layer 140.

The base layer 110 may provide a base surface on which the circuit layer 120 is disposed. The base layer 110 may be a glass substrate, a metal substrate, or a polymer substrate. However, the disclosure should not be limited thereto or thereby, and in an embodiment, the base layer 110 may be an inorganic layer, an organic layer, or a composite material layer.

The base layer 110 may have a multi-layer structure. In an embodiment, the base layer 110 may include a first synthetic resin layer, a silicon oxide (SiOx) layer disposed on the first synthetic resin layer, an amorphous silicon (a-Si) layer disposed on the silicon oxide layer, and a second synthetic resin layer disposed on the amorphous silicon layer, for example. The silicon oxide layer and the amorphous silicon layer may be also referred to as a base barrier layer.

Each of the first and second synthetic resin layers may include a polyimide-based resin. In addition, each of the first and second synthetic resin layers may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In the disclosure, the term “X-based resin”, as used herein, refers to the resin that includes a functional group of X.

The circuit layer 120 may be disposed on the base layer 110. The circuit layer 120 may include an insulating layer, a semiconductor pattern, a conductive pattern, and a signal line. An insulating layer, a semiconductor layer, and a conductive layer may be formed on the base layer 110 by a coating or depositing process. Then, the insulating layer, the semiconductor layer, and the conductive layer may be selectively patterned through several photolithography processes. The semiconductor pattern, the conductive pattern, and the signal line included in the circuit layer 120 may be formed.

The light-emitting element layer 130 may be disposed on the circuit layer 120. The light-emitting element layer 130 may include a light-emitting element. In an embodiment, the light-emitting element layer 130 may include an organic light-emitting material, a quantum dot, a quantum rod, a micro light-emitting diode (“micro-LED”), or a nano-LED, for example.

The encapsulation layer 140 may be disposed on the light-emitting element layer 130. The encapsulation layer 140 may protect the light-emitting element layer 130 from moisture, oxygen, and a foreign substance such as dust particles.

The input sensing layer ISP may be formed on the display panel DP through successive processes. In this case, the input sensing layer ISP may be disposed directly on the display panel DP. In the following descriptions, the expression “The input sensing layer ISP is disposed directly on the display panel DP” means that no intervening elements are between the input sensing layer ISP and the display panel DP. That is, a separate adhesive member may not be disposed between the input sensing layer ISP and the display panel DP. In an alternative embodiment, the input sensing layer ISP may be coupled with the display panel DP by an adhesive member. The adhesive member may be a conventional adhesive.

FIG. 5 is an equivalent circuit diagram of an embodiment of a pixel according to the disclosure.

Each of the pixels PX (refer to FIG. 3) may include at least one sub-pixel PXSij. FIG. 5 shows an equivalent circuit diagram of the sub-pixel PXSij connected to an i-th data line DLi among the data lines DL1 to DLm, a j-th scan line SLj among the scan lines SL1 to SLn, and a j-th light emission control line EMLj among the light emission control lines EML1 to EMLn.

Referring to FIGS. 4 and 5, the sub-pixel PXSij may include a pixel circuit PXC and at least one light-emitting element ED. The pixel circuit PXC may be disposed in the circuit layer 120, and the light-emitting element ED may be disposed in the light-emitting element layer 130. The pixel circuit PXC may control an emission of the light-emitting element ED.

The pixel circuit PXC may include first, second, third, fourth, fifth, sixth, seventh, and eighth transistors T1, T2, T3, T4, T5, T6, T7, and T8, a first capacitor Cst, and a second capacitor Cse. The light-emitting element ED may be a light-emitting diode. In the illustrated embodiment, a structure in which one sub-pixel PXSij includes one light-emitting element ED will be described as an illustrative embodiment.

The first to eighth transistors T1 to T8 may be N-type transistors each including oxide semiconductor as its semiconductor layer, however, the disclosure should not be limited thereto or thereby. In an embodiment, the first to eighth transistors T1 to T8 may be P-type transistors each including a low-temperature polycrystalline silicon (“LTPS”) semiconductor layer. In an embodiment, at least one of the first to eighth transistors T1 to T8 may be the N-type transistor, and a remaining (the other) one or remaining (the other) ones of the first to eighth transistors T1 to T8 may be the P-type transistor. In addition, the configuration of the pixel circuit PXC according to the disclosure should not be limited to that shown in FIG. 5. The pixel circuit PXC shown in FIG. 5 is merely one of embodiments, and the configuration of the pixel circuit PXC may be changed.

The scan line SLj may include a first scan line GILj, a second scan line GCLj, a third scan line GWLj, and a fourth scan line GBLj. The first, second, third, and fourth scan lines GILj, GCLj, GWLj, and GBLj may transmit first, second, third, and fourth scan signals GIj, GCj, GWj, and GBj, respectively, and the light emission control line EMLj may transmit a light emission control signal EMj. The data line DLi may transmit a data signal Di.

The data signal Di may have a voltage level corresponding to the input data RGB (refer to FIG. 3) input into the display panel DP (refer to FIG. 3). First, second, third, fourth, and fifth voltage lines VL1, VL2, VL3, VL4, and VL5 may transmit the driving voltage ELVDD, the power supply voltage ELVSS, the initialization voltage VINT, the anode initialization voltage VAINT, and the bias voltage Vbias, respectively.

The first transistor T1 may include a first electrode connected to the first voltage line VL1 via the fifth transistor T5, a second electrode electrically connected to an anode of the light-emitting element ED via the sixth transistor T6, and a gate electrode connected to one end of the first capacitor Cst. The first transistor T1 may receive the data signal Di transmitted by the data line DLi in response to a switching operation of the second transistor T2 and may supply a driving current led to the light-emitting element ED.

The second transistor T2 may include a first electrode connected to the data line DLi, a second electrode connected to the first electrode of the first transistor T1, and a gate electrode connected to the third scan line GWLj. The second transistor T2 may be turned on in response to the third scan signal GWj applied thereto via the third scan line GWLj and may transmit the data signal Di applied thereto via the data line DLi to the first electrode of the first transistor T1.

The third transistor T3 may include a first electrode connected to the gate electrode of the first transistor T1, a second electrode connected to the second electrode of the first transistor T1, and a gate electrode connected to the second scan line GCLj. The third transistor T3 may be turned on in response to the second scan signal GCj applied thereto via the second scan line GCLj and may connect the gate electrode and the second electrode of the first transistor T1 to each other to allow the first transistor T1 to be connected in a diode configuration. The third transistor T3 may be implemented as a dual transistor.

The fourth transistor T4 may include a first electrode connected to the gate electrode of the first transistor T1, a second electrode connected to the third voltage line VL3 through which the initialization voltage VINT is transmitted, and a gate electrode connected to the scan line GILj. The fourth transistor T4 may be turned on in response to the first signal GIj applied thereto via the first scan line GILj. The turned-on fourth transistor T4 may transmit the initialization voltage VINT to the gate electrode of the first transistor T1 to initialize a voltage of the gate electrode of the first transistor T1. The fourth transistor T4 may be implemented as a dual transistor.

The fifth transistor T5 may include a first electrode connected to the first voltage line VL1, a second electrode connected to the first electrode of the first transistor T1, and a gate electrode connected to the light emission control line EMLj.

The sixth transistor T6 may include a first electrode connected to the second electrode of the first transistor T1, a second electrode connected to the anode of the light-emitting element ED, and a gate electrode connected to the light emission control line EMLj.

The fifth transistor T5 and the sixth transistor T6 may be substantially simultaneously turned on in response to the light emission control signal EMj applied thereto via the light emission control line EMLj, and thus, the driving voltage ELVDD may be compensated for by the first transistor T1 connected in the diode configuration and may be transmitted to the light-emitting element ED.

The seventh transistor T7 may include a first electrode connected to the anode of the light-emitting element ED, a second electrode connected to the fourth voltage line VL4, and a gate electrode connected to the fourth scan line GBLj. The seventh transistor T7 may be turned on in response to the fourth scan signal GBj applied thereto via the fourth scan line GBLj and may bypass a current of the anode of the light-emitting element ED to the fourth voltage line VL4.

The eighth transistor T8 may include a first electrode connected to the first electrode of the first transistor T1, a second electrode connected to the fifth voltage line VL5, and a gate electrode connected to the fourth scan line GBLj. The eighth transistor T8 may be turned on in response to the fourth scan signal GBj applied thereto via the fourth scan line GBLj and may transmit the bias voltage Vbias to the first electrode of the first transistor T1.

The one end of the capacitor Cst may be connected to the gate electrode of the first transistor T1, and an opposite end of the first capacitor Cst may be connected to the first voltage line VL1. A cathode of the light-emitting diode ED may be connected to the second voltage line VL2 that transmits the power supply voltage ELVSS. One end of the second capacitor Cse may be connected to the first electrode of the first transistor T1, and an opposite end of the second capacitor Cse may be connected to the first voltage line VL1.

The structure of the sub-pixel PXSij should not be limited to the structure shown in FIG. 5, and the number of the transistors and the number of the capacitors, which are included in one sub-pixel PXSij, and the connection relation thereof may be changed in various ways.

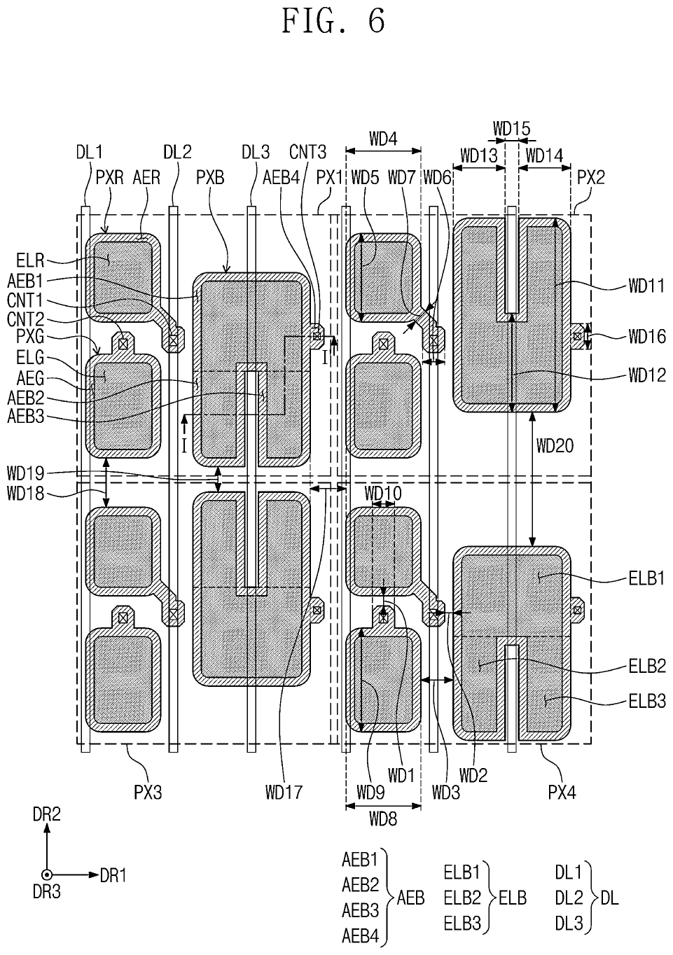

FIG. 6 is a plan view of an embodiment of a portion of the display device according to the disclosure.

A first sub-pixel PXR, a second sub-pixel PXG, and a third sub-pixel PXB shown in FIG. 6 may have substantially the same circuit configuration as the equivalent circuit of the sub-pixel PXSij shown in FIG. 5.

Referring to FIGS. 4 to 6, the display panel DP may include the pixels PX and the data lines DL. FIG. 6 shows four pixels among the pixels PX. The data line DL may include a first data line DL1, a second data line DL2, and a third data line DL3.

The pixels PX may include a first pixel PX1, a second pixel PX2, a third pixel PX3, and a fourth pixel PX4. The second pixel PX2 may be spaced apart from the first pixel PX1 in the first direction DR1. The third pixel PX3 may be spaced apart from the first pixel PX1 in the direction opposite to the second direction DR2. The fourth pixel PX4 may be spaced apart from the second pixel PX2 in the direction opposite to the second direction DR2. The first to fourth pixels PX1 to PX4 may include the same components, and only the arrangements of components of the first to fourth pixels PX1 to PX4 may be different from each other.

The first pixel PX1 may include a first sub-pixel PXR, a second sub-pixel PXG, and a third sub-pixel PXB. Each of the first sub-pixel PXR, the second sub-pixel PXG, and the third sub-pixel PXB may correspond to the sub-pixel PXSij.

The second sub-pixel PXG may be disposed spaced apart from the first sub-pixel PXR in the direction opposite to the second direction DR2. In this case, a distance between the first sub-pixel PXR and the second sub-pixel PXG may be also referred to as a first width WD1. In an embodiment, the first width WD1 may be within a range from about 3.50 micrometers (μm) to about 6.40 μm. In detail, the first width WD1 may be about 3.89 μm.

The third sub-pixel PXB may be disposed spaced apart from the first sub-pixel PXR in the first direction DR1 by a second width WD2. The second width WD2 may be within a range from about 3.0 μm to about 6.0 μm. In an embodiment, the second width WD2 may be about 3.1 μm.

The third sub-pixel PXB may be disposed spaced apart from the second sub-pixel PXG in the first direction DR1 by a third width WD3. The third width WD3 may be within a range from about 12.50 μm to about 15.20 μm. In an embodiment, the third width WD3 may be about 12.66 μm.

The first data line DL1, the second data line DL2, and the third data line DL3 may be arranged in the circuit layer 120.

The light-emitting element ED of the first sub-pixel PXR may include a first anode AER and a first light-emitting layer ELR. The first anode AER and the first light-emitting layer ELR may be disposed on the light-emitting element layer 130.

The first anode AER may be electrically connected to the pixel circuit PXC of the first sub-pixel PXR through a first contact hole CNT1. The first light-emitting layer ELR may be disposed on the first anode AER. The first light-emitting layer ELR may emit a red light.

In the plan view, the first anode AER may overlap the first data line DL1, and the first light-emitting layer ELR may not overlap the first data line DL1.

In the plan view, the first anode AER may cover the first light-emitting layer ELR. That is, in the plan view, the first anode AER may have an area greater than an area of the first light-emitting layer ELR.

The first anode AER disposed under the first light-emitting layer ELR may have a fourth width WD4 in the first direction DR1. The fourth width WD4 may be within a range from about 28.40 μm to about 31.00 μm. In an embodiment, the fourth width WD4 may be about 30.96 μm. The first anode AER disposed under the first light-emitting layer ELR may have a fifth width WD5 in the second direction DR2. The fifth width WD5 may be within a range from about 34.40 μm to about 36.70 μm. In an embodiment, the fifth width WD5 may be about 36.64 μm.

The first anode AER disposed on the first contact hole CNT1 may have a sixth width WD6 in the first direction DR1. The sixth width WD6 may be within a range from about 6.7 μm to about 9.5 μm. In an embodiment, the sixth width WD6 may be about 9.2 μm.

A portion of the first anode AER, which connects a portion of the first anode AER disposed on the first contact hole CNT1 and a portion of the first anode AER disposed under the first light-emitting layer ELR, may have a seventh width WD7. The seventh width WD7 may be within a range from about 3.40 μm to about 6.00 μm. In an embodiment, the seventh width WD7 may be about 5.91 μm.

The light-emitting element ED of the second sub-pixel PXG may include a second anode AEG and a second light-emitting layer ELG. The second anode AEG and the second light-emitting layer ELG may be disposed on the light-emitting element layer 130.

The second anode AEG may be electrically connected to the pixel circuit PXC of the second sub-pixel PXG through a second contact hole CNT2. The second light-emitting layer ELG may be disposed on the second anode AEG. The second light-emitting layer ELG may emit a green light.

In the plan view, the second anode AEG may overlap the second data line DL2, and the second light-emitting layer ELG may not overlap the second data line DL2.

In the plan view, the second anode AEG may cover the second light-emitting layer ELG. That is, in the plan view, the second anode AEG may have an area greater than an area of the second light-emitting layer ELG.

The second anode AEG disposed under the second light-emitting layer ELG may have an eighth width WD8 in the first direction DR1. The eighth width WD8 may be within a range from about 28.40 μm to about 31.00 μm. In an embodiment, the eighth width WD8 may be about 30.96 μm. The second anode AEG disposed under the second light-emitting layer ELG may have a ninth width WD9 in the second direction DR2. The ninth width WD9 may be within a range from about 40.30 μm to about 42.90 μm. In an embodiment, the ninth width WD9 may be about 42.84 μm.

The second anode AEG disposed on the second contact hole CNT2 may have a tenth width WD10 in the first direction DR1. The tenth width WD10 may be within a range from about 6.6 μm to about 9.3 μm. In an embodiment, the tenth width WD10 may be about 9.2 μm.

The light-emitting element ED of the third sub-pixel PXB may include a third anode AEB and a third light-emitting layer ELB. The third anode AEB and the third light-emitting layer ELB may be disposed on the light-emitting element layer 130.

The third anode AEB may be electrically connected to the pixel circuit PXC of the third sub-pixel PXB through a third contact hole CNT3. The third light-emitting layer ELB may be disposed on the third anode AEB. The third light-emitting layer ELB may emit a blue light.

In the plan view, the third anode AEB may cover the third light-emitting layer ELB. That is, in the plan view, the third anode AEB may have an area greater than an area of the third light-emitting layer ELB.

The third anode AEB disposed under the third light-emitting layer ELB may have an eleventh width WD11 in the second direction DR2. The eleventh width WD11 may be within a range from about 76.90 μm to about 79.50 μm. In an embodiment, the eleventh width WD11 may be about 79.42 μm.

The third anode AEB may include a first portion AEB1, a second portion AEB2, a third portion AEB3, and a fourth portion AEB4.

The first portion AEB1, the second portion AEB2, and the third portion AEB3 may be disposed under the third light-emitting layer ELB. That is, in the plan view, the first portion AEB1, the second portion AEB2, and the third portion AEB3 may overlap the third light-emitting layer ELB.

The fourth portion AEB4 may be disposed on the third contact hole CNT3. That is, in the plan view, the fourth portion AEB4 may overlap the third contact hole CNT3.

The first portion AEB1, the second portion AEB2, the third portion AEB3, and the fourth portion AEB4 may be provided integrally with each other.

The first portion AEB1 may have a twelfth width WD12 in the second direction DR2. The twelfth width WD12 may be within a range from about 38.10 μm to about 40.70 μm. In an embodiment, the twelfth width WD12 may be about 40.64 μm.

The second portion AEB2 may extend from the first portion AEB1 to protrude in a direction parallel to the second direction DR2. The second portion AEB2 may have a thirteenth width WD13 in the first direction DR1. The thirteenth width WD13 may be within a range from about 20.20 μm to about 22.80 μm. In an embodiment, the thirteenth width WD13 may be about 22.71 μm.

The third portion AEB3 may extend from the first portion AEB1 to protrude in the direction parallel to the second direction DR2. The third portion AEB3 may have a fourteenth width WD14 in the first direction DR1. The fourteenth width WD14 may be within a range from about 20.20 μm to about 22.80 μm. In an embodiment, the fourteenth width WD14 may be about 22.71 μm.

The second portion AEB2 and the third portion AEB3 may be spaced apart from each other in the first direction DR1 and may face each other. A distance between the second portion AEB2 and the third portion AEB3 may be also referred to as a fifteenth width WD15. The fifteenth width WD15 may be within a range from about 3.0 μm to about 6.0 μm. In an embodiment, the fifteenth width WD15 may be about 3.10 μm.

In the plan view, the first portion AEB1 may overlap the third data line DL3, and the second portion AEB2 and the third portion AEB3 may not overlap the third data line DL3. The third data line DL3 may have a thickness smaller than the fifteenth width WD15.

The fourth portion AEB4 may extend from the first portion AEB1 to protrude in the first direction DR1, however, it should not be limited thereto or thereby. In an embodiment, the fourth portion AEB4 may extend from the second portion AEB2 or the third portion AEB3 to protrude. That is, the fourth portion AEB4 may protrude from one of the first to third portions AEB1 to AEB3.

The fourth portion AEB4 may have a sixteenth width WD16 in the second direction DR2. The sixteenth width WD16 may be within a range from about 7.60 μm to about 10.3 μm. In an embodiment, the sixteenth width WD16 may be about 10.20 μm.

The third light-emitting layer ELB may be disposed on the third anode AEB. The third light-emitting layer ELB may include a first light-emitting portion ELB1, a second light-emitting portion ELB2, and a third light-emitting portion ELB3. The first to third light-emitting portions ELB1 to ELB3 may be disposed on the first to third portions AEB1 to AEB3, respectively.

The first light-emitting portion ELB1 may have a shape corresponding to a shape of the first portion AEB1. In the plan view, the first light-emitting portion ELB1 may overlap the first portion AEB1.

The second light-emitting portion ELB2 may have a shape corresponding to a shape of the second portion AEB2. In the plan view, the second light-emitting portion ELB2 may overlap the second portion AEB2.

The third light-emitting portion ELB3 may have a shape corresponding to a shape of the third portion AEB3. In the plan view, the third light-emitting portion ELB3 may overlap the third portion AEB3.

In the plan view, the third light-emitting layer ELB may not overlap the fourth portion AEB4.

The first light-emitting portion ELB1, the second light-emitting portion ELB2, and the third light-emitting portion ELB3 may be provided integrally with each other.

The first sub-pixel PXR and the second sub-pixel PXG of the second pixel PX2 may be spaced apart from the first portion AEB1 to the third portion AEB3 of the third sub-pixel PXB of the first pixel PX1 in the first direction DR1 by a seventeenth width WD17. The seventeenth width WD17 may be within a range from about 12.60 μm to about 15.20 μm. In an embodiment, the seventeenth width WD17 may be about 12.66 μm.

The first sub-pixel PXR of the third pixel PX3 may be spaced apart from the second sub-pixel PXG of the first pixel PX1 in the direction parallel to the second direction DR2 by an eighteenth width WD18. The eighteenth width WD18 may be within a range from about 12.60 μm to about 15.20 μm. In an embodiment, the eighteenth width WD18 may be about 12.66μ m.

The third sub-pixel PXB of the third pixel PX3 may be spaced apart from the third sub-pixel PXB of the first pixel PX1 in the direction parallel to the second direction DR2 by a nineteenth width WD19. The nineteenth width WD19 may be within a range from about 3.0 μm to about 6.0 μm. In an embodiment, the nineteenth width WD19 may be about 3.10 μm.

The second portion AEB2 and the third portion AEB3 of the first pixel PX1 may be disposed to respectively face the second portion AEB2 and the third portion AEB3 of the third pixel PX3.

The third sub-pixel PXB of the fourth pixel PX4 may be spaced apart from the third sub-pixel PXB of the second pixel PX2 in the direction parallel to the second direction DR2 by a twentieth width WD20. The twentieth width WD20 may be greater than the nineteenth width WD19. The twentieth width WD20 may be within a range from about 47.60 μm to about 50.20 μm. In an embodiment, the twentieth width WD20 may be about 47.66 μm. The first portion AEB1 of the fourth pixel PX4 may be disposed to face the first portion AEB1 of the second pixel PX2.

Different from the disclosure, there may be no gap between the second portion and the third portion. That is, in the plan view, the second portion and the third portion may overlap the third data line. In this case, a parasitic capacitance is generated between the third anode and the third data line, and thus, load of the data signal applied to the third data line increases. As a result, the third data line may be insufficiently charged. However, according to the disclosure, the third data line DL3 may be disposed between the second portion AEB2 and the third portion AEB3. In the plan view, since the third data line DL3 does not overlap the second portion AEB2 and the third portion AEB3, the parasitic capacitance may be reduced between the third data line DL3 and the second portion AEB2 and the third portion AEB3. The increase in load of the data signal applied to the third data line DL3 due to the parasitic capacitance may be prevented, and thus, the third data line DL3 may be prevented from being insufficiently charged. Therefore, the reliability of the display device DD may be improved.

In addition, different from the disclosure, when there is no gap between the second portion and the third portion, an outgas generated from the circuit layer is not discharged outwardly, and the lifespan of the third light-emitting layer is reduced. However, according to the disclosure, there is a gap between the second portion AEB2 and the third portion AEB3, and the outgas generated from the circuit layer 120 may be smoothly discharged, and thus, a pixel shrinkage phenomenon may be reduced, and lifespan of the third light-emitting layer ELB may increase. Accordingly, the reliability of the display device DD may be improved.

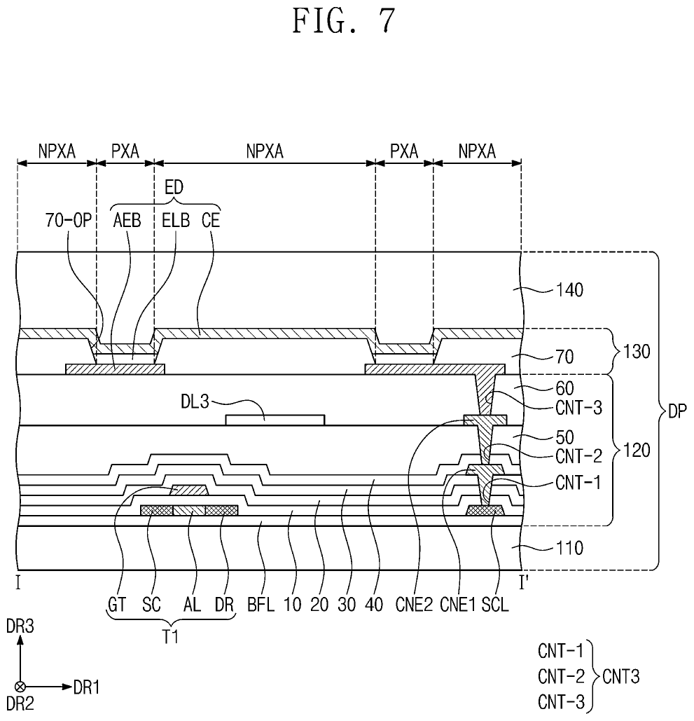

FIG. 7 is a cross-sectional view taken along line I-I′ of FIG. 6 according to the disclosure.

Referring to FIGS. 6 and 7, the display panel DP may include the base layer 110, the circuit layer 120, the light-emitting element layer 130, and the encapsulation layer 140.

At least one inorganic layer may be formed on an upper surface of the base layer 110. The inorganic layer may include at least one of aluminum oxide, titanium oxide, silicon oxide, silicon nitride, silicon oxynitride, zirconium oxide, and hafnium oxide. The inorganic layer may be formed in multiple layers. The inorganic layers formed in multiple layers may form a barrier layer and/or a buffer layer.

The base layer 110 may have a multi-layer structure. In an embodiment, the base layer 110 may include a first synthetic resin layer, a silicon oxide (SiOx) layer disposed on the first synthetic resin layer, an amorphous silicon (a-Si) layer disposed on the silicon oxide layer, and a second synthetic resin layer disposed on the amorphous silicon layer, for example. The silicon oxide layer and the amorphous silicon layer may be also referred to as a base barrier layer.

In the illustrated embodiment, the display panel DP may include the buffer layer BFL. The buffer layer BFL may increase an adhesive force between the base layer 110 and the semiconductor pattern. The buffer layer BFL may include at least one of silicon oxide, silicon nitride, and silicon oxynitride. In an embodiment, the buffer layer BFL may have a stack structure in which a silicon oxide layer and a silicon nitride layer are alternately stacked with each other, for example.

The semiconductor pattern may correspond to one of patterns of the semiconductor layer disposed on the buffer layer BFL. The semiconductor pattern may include a metal oxide. The semiconductor pattern may include polysilicon, however, it should not be limited thereto or thereby. The semiconductor pattern may include amorphous silicon, relatively low temperature polycrystalline silicon, or oxide semiconductor.

The metal oxide semiconductor may include a crystalline or amorphous oxide semiconductor. In an embodiment, the oxide semiconductor may include the metal oxide of metals, such as zinc (Zn), indium (In), gallium (Ga), tin (Sn), titanium (Ti), etc., or a combination of the metal, such as zinc (Zn), indium (In), gallium (Ga), tin (Sn), titanium (Ti), etc., and oxides thereof. The oxide semiconductor may include indium-tin oxide (“ITO”), indium-gallium-zinc oxide (“IGZO”), zinc oxide (ZnO), indium-zinc oxide (“IZO”), zinc-indium oxide (“ZIO”), indium oxide (InO), titanium oxide (TiO), indium-zinc-tin oxide (“IZTO”), zinc-tin oxide (“ZTO”), or the like.

The semiconductor pattern may include a plurality of areas distinguished from each other depending on whether the metal oxide is reduced or not. An area (hereinafter, also referred to as a reduced area) where the metal oxide is reduced may have a conductivity higher than that of an area (hereinafter, also referred to as a non-reduced area) where the metal oxide is not reduced. The reduced area may substantially act as a source/drain or a signal line of the transistor. The non-reduced area may substantially correspond to a semiconductor area (or a channel) of the transistor. In other words, a portion of the semiconductor pattern may be the semiconductor area of the transistor, another portion of the semiconductor pattern may be the source/drain of the transistor, and a remaining (the other) portion of the semiconductor pattern may be a signal transmission area.

Each of the pixels may have an equivalent circuit that includes five transistors, two capacitors, and the light-emitting element, however, the equivalent circuit of the pixels may be changed in various ways. FIG. 7 shows one transistor T1 and the light-emitting element ED included in the pixel.

A source area SC, an active area AL, and a drain area DR of the transistor T1 may be formed from the semiconductor pattern. The source area SC and the drain area DR may extend in opposite directions to each other from the active area AL in a cross-section.

FIG. 7 shows a portion of a connection signal line SCL formed from the semiconductor pattern. Although not shown in drawing figures, the connection signal line SCL may be electrically connected to the drain area DR of the transistor T1 in a plane.

A first insulating layer 10 may be disposed on the buffer layer BFL. The first insulating layer 10 may commonly overlap the pixels and may cover the semiconductor pattern. The first insulating layer 10 may be an inorganic layer and/or an organic layer and may have a single-layer or multi-layer structure. The first insulating layer 10 may include at least one of aluminum oxide, titanium oxide, silicon oxide, silicon nitride, silicon oxynitride, zirconium oxide, and hafnium oxide. In the illustrated embodiment, the first insulating layer 10 may have a single-layer structure of a silicon oxide layer. Not only the first insulating layer 10, but also insulating layers of the circuit layer 120 described later may be an inorganic layer and/or an organic layer and may have a single-layer or multi-layer structure. The inorganic layer may include at least one of the above-mentioned materials, however, it should not be limited thereto.

A gate GT of the first transistor T1 may be disposed on the first insulating layer 10. The first transistor T1 may be disposed on the base layer 110. The gate GT may be a portion of a metal pattern. The gate GT may overlap the active area AL. The gate GT may be used as a mask in a process of doping the semiconductor pattern.

A second insulating layer 20 may be disposed on the first insulating layer 10 and may cover the gate GT. The second insulating layer 20 may commonly overlap the pixels. The second insulating layer 20 may be an inorganic layer and/or an organic layer and may have a single-layer or multi-layer structure. The second insulating layer 20 may include at least one of silicon oxide, silicon nitride, and silicon oxynitride. In the illustrated embodiment, the second insulating layer 20 may have a multi-layer structure of a silicon oxide layer and a silicon nitride layer.

A third insulating layer 30 may be disposed on the second insulating layer 20. The third insulating layer 30 may have a single-layer structure or a multi-layer structure. In an embodiment, the third insulating layer 30 may have the multi-layer structure of a silicon oxide layer and a silicon nitride layer.

The first transistor T1 may be electrically connected to the light-emitting element layer 130 through the third contact hole CNT3. The third contact hole CNT3 may include contact holes CNT-1, CNT-2, and CNT-3.

A connection electrode CNE may include first, second, and third connection electrodes CNE1, CNE2, and CNE3. The first connection electrode CNE1 may be disposed on the third insulating layer 30. The first connection electrode CNE1 may be connected to the connection signal line SCL via the contact hole CNT-1 defined through the first, second, and third insulating layers 10, 20, and 30.

A fourth insulating layer 40 may be disposed on the third insulating layer 30. The fourth insulating layer 40 may have a single-layer structure of a silicon oxide layer. A fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be connected to the first connection electrode CNE1 via the contact hole CNT-2 defined through the fourth insulating layer 40 and the fifth insulating layer 50.

The third data line DL3 may be disposed on the fifth insulating layer 50. The third data line DL3 may be disposed in the same layer as the second connection electrode CNE2. The third data line DL3 may be disposed on the first transistor T1. However, the disclosure should not be limited thereto or thereby, and the arrangement of the third data line DL3 should not be limited thereto or thereby. In an embodiment, the third data line DL3 may be disposed between the first transistor T1 and the third anode (also referred to as a first electrode) AEB.

A sixth insulating layer 60 may be disposed on the fifth insulating layer 50 and may cover the second connection electrode CNE2 and the third data line DL3. The sixth insulating layer 60 may be an organic layer.

The light-emitting element layer 130 may be disposed on the circuit layer 120. The light-emitting element layer 130 may include the light-emitting element ED and a pixel definition layer 70. In an embodiment, the light-emitting element layer 130 may include an organic light-emitting material, an inorganic light-emitting material, an organic-inorganic light-emitting material, a quantum dot, a quantum rod, a micro-LED, or a nano-LED, for example. Hereinafter, an organic light-emitting element will be described as the light-emitting element ED, however, the light-emitting element should not be particularly limited.

The light-emitting element ED may include the third anode AEB, the third light-emitting layer ELB, and a cathode (also referred to as a second electrode) CE.

The third anode AEB may be disposed on the sixth insulating layer 60. The third anode AEB may be connected to the second connection electrode CNE2 via the contact hole CNT-3 defined through the sixth insulating layer 60. That is, the connection electrode CNE may electrically connect the first transistor T1 and the light-emitting element layer 130.

Portions of the third anode AEB may be disposed spaced apart from each other with a predetermined distance. In an embodiment, a portion of the third anode AEB, which is disposed at a left side in FIG. 7, may be the second portion AEB2 (refer to FIG. 6), and a portion of the third anode AEB, which is disposed at a right side in FIG. 7, may be the third portion AEB3 (refer to FIG. 6).

In the plan view, the third data line DL3 may not overlap the second portion AEB2 and the third portion AEB3. That is, the third data line DL3 may be disposed between the second portion AEB2 and the third portion AEB3.

In the plan view, the third data line DL3 may not overlap at least a portion of the third anode AEB. The parasitic capacitance generated between the third anode AEB and the third data line DL3 may be reduced. The phenomenon in which the increase in load of the data signal applied to third data line DL3 due to the parasitic capacitance may be prevented, and thus, the third data line DL3 may be prevented from being insufficiently charged. Accordingly, the reliability of the display device DD may be improved.

The pixel definition layer 70 may be disposed on the sixth insulating layer 60 and may cover a portion of the third anode AEB. An opening 70-OP may be defined through the pixel definition layer 70. At least a portion of the third anode AEB may be exposed through the opening 70-OP of the pixel definition layer 70.

The display area DA (refer to FIG. 1) may include a light-emitting area PXA and a non-light-emitting area NPXA next (adjacent) to the light-emitting area PXA. The non-light-emitting area NPXA may surround the light-emitting area PXA. In the illustrated embodiment, the light-emitting area PXA may be defined to correspond to the portion of the third anode AEB exposed through the opening 70-OP.

The third light-emitting layer ELB may be disposed on the third anode AEB. The third light-emitting layer ELB may be disposed in an area corresponding to the opening 70-OP. The third light-emitting layer ELB may emit the blue light. In the plan view, the third light-emitting layer ELB may not overlap the third contact hole CNT3.

The cathode CE may be disposed on the third light-emitting layer ELB. The cathode CE may have an integral shape and may be commonly disposed over the pixels.

Although not shown in drawing figures, a hole control layer may be disposed between the third anode AEB and the third light-emitting layer ELB. The hole control layer may be commonly disposed in the light-emitting area PXA and the non-light-emitting area NPXA. The hole control layer may include a hole transport layer and may further include a hole injection layer. An electron control layer may be disposed between the third light-emitting layer ELB and the cathode CE. The electron control layer may include an electron transport layer and may further include an electron injection layer. The hole control layer and the electron control layer may be commonly formed in the plural pixels using an open mask or an inkjet process.

The encapsulation layer 140 may be disposed on the light-emitting element layer 130. The encapsulation layer 140 may include an inorganic layer, an organic layer, and an inorganic layer, which are sequentially stacked, however, layers of the encapsulation layer 140 should not be limited thereto or thereby. The inorganic layers may protect the light-emitting element layer 130 from moisture and oxygen, and the organic layer may protect the light-emitting element layer 130 from a foreign substance such as dust particles. Each of the inorganic layers may include a silicon nitride layer, a silicon oxynitride layer, a silicon oxide layer, a titanium oxide layer, or an aluminum oxide layer. The organic layer may include an acrylic-based organic layer, however, it should not be limited thereto or thereby.

Different from the disclosure, in the plan view, the third light-emitting layer may overlap the third contact hole. In this case, as the third contact hole is defined, the fourth insulating layer disposed under the third light-emitting layer may not be flat. Accordingly, a color deviation may occur as a light reflectance of the third light-emitting layer varies depending on its area. However, according to the disclosure, in the plan view, the third light-emitting layer ELB may not overlap the third contact hole CNT3. When the third contact hole CNT3 is defined, the insulating layers disposed under the third light-emitting layer ELB may be stacked flatly. Therefore, the light reflectance of the third light-emitting layer ELB may be maintained at a constant level, and thus, the color deviation may be prevented. Accordingly, the display quality of the display device DD (refer to FIG. 1) may be improved.

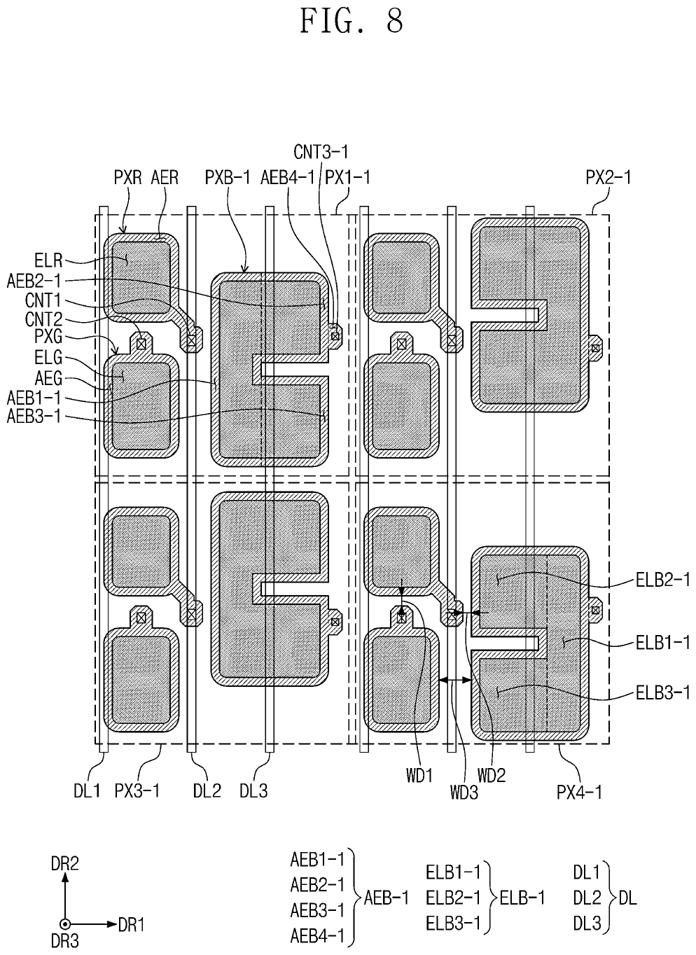

FIG. 8 is a plan view of an embodiment of a portion of a display device according to the disclosure. In FIG. 8, the same reference numerals denote the same elements in FIG. 6, and thus, detailed descriptions of the same elements will be omitted.

Referring to FIGS. 3, 4, 5, and 8, a display panel (refer to DP of FIG. 4) may include a plurality of pixels (refer to PX of FIG. 3) and a data line DL. FIG. 8 shows four pixels among the pixels PX.

The pixels PX may include a first pixel PX1-1, a second pixel PX2-1, a third pixel PX3-1, and a fourth pixel PX4-1. The second pixel PX2-1 may be spaced apart from the first pixel PX1-1 in the first direction DR1. The third pixel PX3-1 may be spaced apart from the first pixel PX1-1 in the direction parallel to the second direction DR2. The fourth pixel PX4-1 may be spaced apart from the second pixel PX2-1 in the direction parallel to the second direction DR2. The first to fourth pixels PX1-1 to PX4-1 may include the same components, and only the arrangements of components of the first to fourth pixels PX1-1 to PX4-1 may be different from each other.

The first pixel PX1-1 may include a first sub-pixel PXR, a second sub-pixel PXG, and a third sub-pixel PXB-1. Each of the first sub-pixel PXR, the second sub-pixel PXG, and the third sub-pixel PXB-1 may correspond to a sub-pixel (refer to PXSij of FIG. 5).

The third sub-pixel PXB-1 may be disposed spaced apart from the first sub-pixel PXR in the first direction DR1 by a second width WD2.

The third sub-pixel PXB-1 may be disposed spaced apart from the second sub-pixel PXG in the first direction DR1 by a third width WD3.

A light-emitting element ED of the third sub-pixel PXB-1 may include a third anode AEB-1 and a third light-emitting layer ELB-1. The third anode AEB-1 and the third light-emitting layer ELB-1 may be disposed on a light-emitting element layer (refer to 130 of FIG. 4).

The third anode AEB-1 may be electrically connected to a pixel circuit PXC of the third sub-pixel PXB-1 through a third contact hole CNT3-1. The third light-emitting layer ELB-1 may be disposed on the third anode AEB-1. The third light-emitting layer ELB-1 may emit a blue light.

In the plan view, the third anode AEB-1 may cover the third light-emitting layer ELB-1. That is, in the plan view, the third anode AEB-1 may have an area greater than an area of the third light-emitting layer ELB-1.

The third anode AEB-1 may include a first portion AEB1-1, a second portion AEB2-1, a third portion AEB3-1, and a fourth portion AEB4-1.

The first portion AEB1-1, the second portion AEB2-1, and the third portion AEB3-1 may be disposed under the third light-emitting layer ELB-1. That is, in the plan view, the first portion AEB1-1, the second portion AEB2-1, and the third portion AEB3-1 may overlap the third light-emitting layer ELB-1.

The fourth portion AEB4-1 may be disposed on the third contact hole CNT3-1. That is, in the plan view, the fourth portion AEB4-1 may overlap the third contact hole CNT3-1.

The first portion AEB1-1, the second portion AEB2-1, the third portion AEB3-1, and the fourth portion AEB4-1 may be provided integrally with each other.

The second portion AEB2-1 may be a portion that extends from the first portion AEB1-1 to protrude in the direction parallel to the first direction DR1. The third portion AEB3-1 may be a portion that extends from the first portion AEB1-1 to protrude in the direction parallel to the first direction DR1. The second portion AEB2-1 and the third portion AEB3-1 may be spaced apart from each other and may face each other in the second direction DR2.

In the plan view, the first portion AEB1-1 may not overlap a third data line DL3, but it should not be limited thereto or thereby. In an embodiment, the first portion AEB1-1 may overlap the third data line DL3.

The fourth portion AEB4-1 may be a portion that extends from the second portion AEB2-1 to protrude in the first direction DR1, however, the disclosure should not be limited thereto or thereby. In an embodiment, the fourth portion AEB4-1 may extend from the first portion AEB1-1 and the third portion AEB3-1 to protrude. That is, the fourth portion AEB4-1 may be a portion protruded from one of the first to third portions AEB1-1 to AEB3-1.

The third light-emitting layer ELB-1 may be disposed on the third anode AEB-1. The third light-emitting layer ELB-1 may include a first light-emitting portion ELB1-1, a second light-emitting portion ELB2-1, and a third light-emitting portion ELB3-1. The first to third light-emitting portions ELB1-1 to ELB3-1 may be disposed on the first to third portions AEB1-1 to AEB3-1, respectively.

The first light-emitting portion ELB1-1 may have a shape corresponding to a shape of the first portion AEB1-1. In the plan view, the first light-emitting portion ELB1-1 may overlap the first portion AEB1-1.

The second light-emitting portion ELB2-1 may have a shape corresponding to a shape of the second portion AEB2-1. In the plan view, the second light-emitting portion ELB2-1 may overlap the second portion AEB2-1.

The third light-emitting portion ELB3-1 may have a shape corresponding to a shape of the third portion AEB3-1. In the plan view, the third light-emitting portion ELB3-1 may overlap the third portion AEB3-1.

In the plan view, the third light-emitting layer ELB-1 may not overlap the fourth portion AEB4-1.

The first light-emitting portion ELB1-1, the second light-emitting portion ELB2-1, and the third light-emitting portion ELB3-1 may be provided integrally with each other.

Different from the disclosure, in the plan view, the third anode may overlap the third data line. In this case, the parasitic capacitance may be generated between the third anode and the third data line, and thus, the load of the data signal applied to the third data line may increase. As a result, the third data line may be insufficiently charged. However, according to the disclosure, the second portion AEB2-1 and the third portion AEB3-1 may be spaced apart from each other, and in the plan view, a space may be defined in the second portion AEB2-1 and the third portion AEB3-1. The third data line DL3 may be disposed to overlap the space. In the plan view, at least a portion of the third data line DL3 may not overlap the third anode AEB-1. The parasitic capacitance generated between the third data line DL3 and the third anode AEB-1 may be reduced compared to when the third data line DL3 overlaps the third anode. The increase in the load of the data signal applied to the third data line DL3 due to the parasitic capacitance may be prevented, and thus, the third data line DL3 may be prevented from being insufficiently charged. Therefore, the reliability of the display device DD may be improved.

In addition, different from the disclosure, when there is no gap between the second portion and the third portion, the outgas generated from the circuit layer is not discharged outwardly, and the lifespan of the third light-emitting layer is reduced. However, according to the disclosure, since there is a gap between the second portion AEB2-1 and the third portion AEB3-1, and the outgas generated from the circuit layer 120 may be smoothly discharged. Thus, the pixel shrinkage phenomenon may be reduced, and the lifespan of the third light-emitting layer ELB-1 may increase. Accordingly, the reliability of the display device DD may be improved.

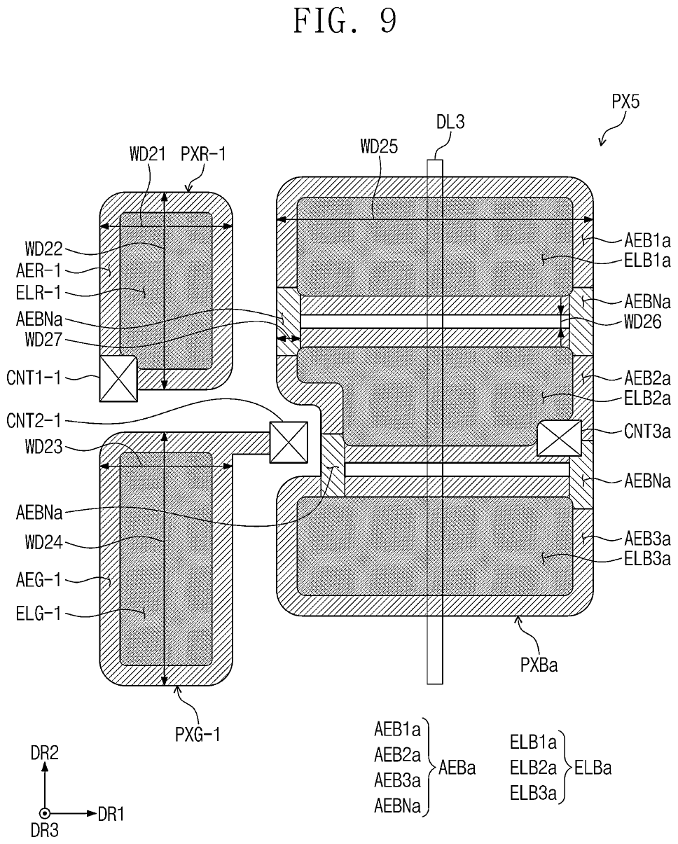

FIG. 9 is a plan view of an embodiment of a portion of a display device according to the disclosure.

Referring to FIGS. 3, 4, 5, and 9, a display panel (refer to DP of FIG. 4) may include a plurality of pixels (refer to PX of FIG. 3) and a plurality of data lines (refer to DL1 to DLm of FIG. 3). FIG. 9 shows a third data line DL3 among the data lines DL1 to DLm. The pixels PX may include a fifth pixel PX5.

The third data line DL3 may be disposed in a circuit layer (refer to 120 of FIG. 4).

The fifth pixel PX5 may include a first sub-pixel PXR-1, a second sub-pixel PXG-1, and a third sub-pixel PXBa. Each of the first sub-pixel PXR-1, the second sub-pixel PXG-1, and the third sub-pixel PXBa may correspond to a sub-pixel (refer to PXSij of FIG. 5).

A light-emitting element ED of the first sub-pixel PXR-1 may be electrically connected to a pixel circuit PXC of the first sub-pixel PXR-1 through a first contact hole CNT1-1. The light-emitting element ED of the first sub-pixel PXR-1 may include a first anode AER-1 and a first light-emitting layer ELR-1. The first anode AER-1 and the first light-emitting layer ELR-1 may be disposed on a light-emitting element layer (refer to 130 of FIG. 4).

The first anode AER-1 may be electrically connected to the pixel circuit PXC of the first sub-pixel PXR-1 through the first contact hole CNT1-1. The first light-emitting layer ELR-1 may be disposed on the first anode AER-1. The first light-emitting layer ELR-1 may emit a red light.

The first anode AER-1 disposed under the first light-emitting layer ELR-1 may have a twenty-first width WD21 in the first direction DR1. The twenty-first width WD21 may be within a range from about 32.50 μm to about 34.00 μm. In an embodiment, the twenty-first width WD21 may be about 33.09 μm. The first anode AER-1 disposed under the first light-emitting layer ELR-1 may have a twenty-second width WD22 in the second direction DR2. The twenty-second width WD22 may be within a range from about 48.50 μm to about 50.00 μm. In an embodiment, the twenty-second width WD22 may be about 49.06 μm.

A light-emitting element ED of the second sub-pixel PXG-1 may be electrically connected to a pixel circuit PXC of the second sub-pixel PXG-1 through a second contact hole CNT2-1. The light-emitting element ED of the second sub-pixel PXG-1 may include a second anode AEG-1 and a second light-emitting layer ELG-1. The second anode AEG-1 and the second light-emitting layer ELG-1 may be disposed on the light-emitting element layer 130.

The second anode AEG-1 may be electrically connected to the pixel circuit PXC of the second sub-pixel PXG-1 through the second contact hole CNT2-1. The second light-emitting layer ELG-1 may be disposed on the second anode AEG-1. The second light-emitting layer ELG-1 may emit a green light.

A portion of the second anode AEG-1 disposed under the second light-emitting layer ELG-1 may have a twenty-third width WD23 in the first direction DR1. The twenty-third width WD23 may be within a range from about 24.00 μm to about 26.00 μm. In an embodiment, the twenty-third width WD23 may be about 25.69 μm. The second anode AEG-1 disposed under the second light-emitting layer ELG-1 may have a twenty-fourth width WD24 in the second direction DR2. The twenty-fourth width WD24 may be within a range from about 62.00 μm to about 64.00 μm. In an embodiment, the twenty-fourth width WD24 may be about 63.25 μm.

A light-emitting element ED of the third sub-pixel PXBa may be electrically connected to a pixel circuit PXC of the third sub-pixel PXBa through a third contact hole CNT3a. In an embodiment, the pixel circuit PXC of the third sub-pixel PXBa may be connected to a third anode AEBa through one third contact hole CNT3a. The light-emitting element ED of the third sub-pixel PXBa may include the third anode AEBa and a third light-emitting layer ELBa. The third anode AEBa and the third light-emitting layer ELBa may be disposed on the light-emitting element layer 130.

The third anode AEBa disposed under the third light-emitting layer ELBa may have a twenty-fifth width WD25 in the first direction DR1. The twenty-fifth width WD25 may be within a range from about 91.00 μm to about 94.00 μm. In an embodiment, the twenty-fifth width WD25 may be about 93.54 μm.

The third anode AEBa may include a first portion AEB1a, a second portion AEB2a, a third portion AEB3a, and a plurality of connection portions AEBNa.

The second portion AEB2a may be disposed spaced apart from the first portion AEB1a in the direction opposite to the second direction DR2. A distance between the first portion AEB1a and the second portion AEB2a may be a twenty-sixth width WD26. The twenty-sixth width WD26 may be within a range from about 2.50 μm to about 4.00 μm. In an embodiment, the twenty-sixth width WD26 may be about 3.1 μm.

The third portion AEB3a may be disposed spaced apart from the second portion AEB2a in the direction opposite to the second direction DR2. A distance between the second portion AEB2a and the third portion AEB3a may be the twenty-sixth width WD26.

The third data line DL3 may be disposed under the third anode AEBa. In the plan view, a portion of the third data line DL3 may not overlap the third anode AEBa.

The connection portions AEBNa may electrically connect the first portion AEB1a, the second portion AEB2a, and the third portion AEB3a, which are spaced apart from each other. Each of the connection portions AEBNa may have a twenty-seventh width WD27 in the first direction DR1. The twenty-seventh width WD27 may be within a range from about 5 μm to about 7 μm. In an embodiment, the twenty-seventh width WD27 may be about 6 μm.

The first portion AEB1a, the second portion AEB2a, the third portion AEB3a, and the connection portions AEBNa may be provided integrally with each other.

In the plan view, the third contact hole CNT3a may overlap the second portion AEB2a and may not overlap the first portion AEB1a and the third portion AEB3a. The third light-emitting layer ELBa may be disposed on the third anode AEBa. The third light-emitting layer ELBa may include a first light-emitting portion ELB1a, a second light-emitting portion ELB2a, and a third light-emitting portion ELB3a. The first to third light-emitting portions ELB1a to ELB3a may be disposed on the first to third portions AEB1a to AEB3a, respectively.

The first light-emitting portion ELB1a may have a shape corresponding to a shape of the first portion AEB1a, the second light-emitting portion ELB2a may have a shape corresponding to a shape of the second portion AEB2a, and the third light-emitting portion ELB3a may have a shape corresponding to a shape of the third portion AEB3a.

Different from the disclosure, when the first light-emitting portion, the second light-emitting portion, and the third light-emitting portion are provided integrally with each other, the outgas generated from the circuit layer is not discharged, and thus, the lifespan of the third light-emitting layer may be reduced. However, according to the disclosure, since there is a gap between the first to third light-emitting portions ELB1a to ELB3a, the outgas generated from the circuit layer may be smoothly discharged. Thus, the pixel shrinkage phenomenon may be reduced, and the lifespan of the third light-emitting layer ELBa may increase. Accordingly, the reliability of the display device DD may be improved.

Different from the disclosure, in the plan view, the third light-emitting layer may overlap the third contact hole. In this case, as the third contact hole is defined, a portion of the circuit layer disposed under the third light-emitting layer may not be flat. Accordingly, the color deviation may occur as the light reflectance of the third light-emitting layer varies. However, according to the disclosure, in the plan view, the third light-emitting layer ELBa may not overlap the third contact hole CNT3a. When the third contact hole CNT3a is defined through the circuit layer 120, a portion of the circuit layer disposed under the third light-emitting layer ELBa may be flat. Therefore, the light reflectance of the third light-emitting layer ELBa may be maintained at a constant level, and thus, the color deviation may be prevented. Accordingly, the display quality of the display device DD may be improved.

Different from the disclosure, in the plan view, the third anode may overlap the third data line. In this case, the parasitic capacitance may be generated between the third anode and the third data line, and thus, the load of the data signal applied to the third data line may increase. As a result, the third data line may be insufficiently charged. However, according to the disclosure, the first portion AEB1a and the second portion AEB2a may be spaced apart from each other, and in the plan view, a first space may be defined between the first portion AEB1a and the second portion AEB2a. The second portion AEB2a and the third portion AEB3a may be spaced apart from each other, and in the plan view, a second space may be defined between the second portion AEB2a and the third portion AEB3a. The third data line DL3 may be disposed to overlap the first and second spaces. In the plan view, at least a portion of the third data line DL3 may not overlap the third anode AEBa. The parasitic capacitance generated between the third data line DL3 and the third anode AEBa may be reduced compared to when the third data line DL3 overlaps the third anode AEBa. The increase in the load of the data signal applied to the third data line DL3 due to the parasitic capacitance may be prevented, and thus, the third data line DL3 may be prevented from being insufficiently charged. Therefore, the reliability of the display device DD may be improved.

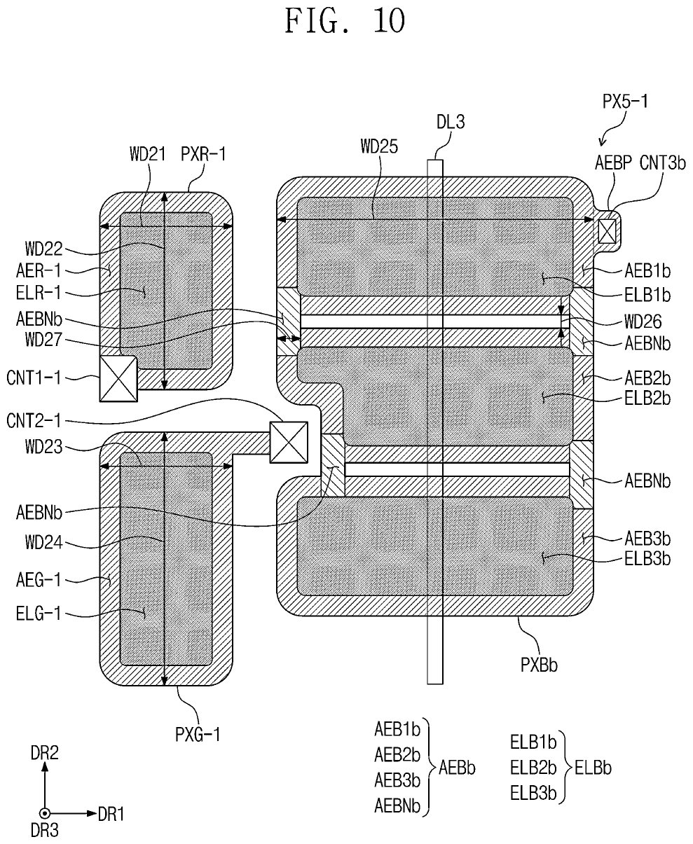

FIG. 10 is a plan view of an embodiment of a portion of a display device according to the disclosure. In FIG. 10, the same reference numerals denote the same elements of FIG. 9, and thus, detailed descriptions of the same elements will be omitted.

Referring to FIGS. 3, 4, 5, and 10, a display panel (refer to DP of FIG. 4) may include a plurality of pixels (refer to PX of FIG. 3). The pixels PX may include a fifth pixel PX5-1.

The fifth pixel PX5-1 may include a first sub-pixel PXR-1, a second sub-pixel PXG-1, and a third sub-pixel PXBb. Each of the first sub-pixel PXR-1, the second sub-pixel PXG-1, and the third sub-pixel PXBb may correspond to a sub-pixel (refer to PXSij of FIG. 5).

A light-emitting element ED of the third sub-pixel PXBb may be electrically connected to a pixel circuit PXC of the third sub-pixel PXBb through a third contact hole CNT3b. In an embodiment, the pixel circuit PXC of the third sub-pixel PXBb may be connected to a third anode AEBb through one third contact hole CNT3b. The light-emitting element ED of the third sub-pixel PXBb may include the third anode AEBb and a third light-emitting layer ELBb. The third anode AEBb and the third light-emitting layer ELBb may be disposed on a light-emitting element layer (refer to 130 of FIG. 4).

The third anode AEBb disposed under the third light-emitting layer ELBb may have a twenty-fifth width WD25 in the first direction DR1. The twenty-fifth width WD25 may be within a range from about 91.00 μm to about 94.00 μm. In an embodiment, the twenty-fifth width WD25 may be about 93.54 μm.

The third anode AEBb may include a first portion AEB1b, a second portion AEB2b, a third portion AEB3b, a plurality of connection portions AEBNb, and a protruding portion AEBP.

The second portion AEB2b may be disposed spaced apart from the first portion AEB1b in the direction opposite to the second direction DR2. A distance between the first portion AEB1b and the second portion AEB2b may be also referred to as a twenty-sixth width WD26. The twenty-sixth width WD26 may be within a range from about 2.50 μm to about 4.00 μm. In an embodiment, the twenty-sixth width WD26 may be about 3.1 μm.

The third portion AEB3b may be disposed spaced apart from the second portion AEB2b in the direction opposite to the second direction DR2. A distance between the second portion AEB2b and the third portion AEB3b may be the same the twenty-sixth width WD26.

A third data line DL3 may be disposed under the third anode AEBb. In the plan view, a portion of the third data line DL3 may not overlap the third anode AEBb.

The connection portions AEBNb may electrically connect the first portion AEB1b, the second portion AEB2b, and the third portion AEB3b to each other. Each of the connection portions AEBNb may have a twenty-seventh width WD27 in the first direction DR1. The twenty-seventh width WD27 may be within a range from about 5 μm to about 7 μm. In an embodiment, the twenty-seventh width WD27 may be about 6 μm.

The protruding portion AEBP may be a portion that extends from the first portion AEB1b to protrude to the first direction DR1, however, the disclosure should not be limited thereto or thereby. In an embodiment, the protruding portion AEBP may be the portion that extends from the second portion AEB2b, the third portion AEB3b, or the connection portions AEBNb to protrude. That is, the protruding portion AEBP may be the portion that extends from one of the second portion AEB2b, the third portion AEB3b, and the connection portions AEBNb.

The first portion AEB1a, the second portion AEB2a, the third portion AEB3a, the connection portions AEBNa, and the protruding portion AEBP may be provided integrally with each other.

In the plan view, the third contact hole CNT3b may overlap the protruding portion AEBP and may not overlap the first to third portions AEB1b to AEB3b. The third light-emitting layer ELBb may be disposed on the third anode AEBb. The third light-emitting layer ELBb may include a first light-emitting portion ELB1b, a second light-emitting portion ELB2b, and a third light-emitting portion ELB3b. The first to third light-emitting portions ELB1b to ELB3b may be disposed on the first to third portions AEB1b to AEB3b, respectively.

The first light-emitting portion ELB1b may have a shape corresponding to a shape of the first portion AEB1b, the second light-emitting portion ELB2b may have a shape corresponding to a shape of the second portion AEB2b, and the third light-emitting portion ELB3b may have a shape corresponding to a shape of the third portion AEB3b.

Different from the disclosure, when the first light-emitting portion, the second light-emitting portion, and the third light-emitting portion are provided integrally with each other, the outgas generated from the circuit layer is not discharged, and thus, the lifespan of the third light-emitting layer may be reduced. However, according to the disclosure, there is a gap between the first to third light-emitting portions ELB1b to ELB3b, and the outgas generated from the circuit layer 120 may be smoothly discharged. Thus, the pixel shrinkage phenomenon may be reduced, and the lifespan of the third light-emitting layer ELBb may increase. Accordingly, the reliability of the display device DD may be improved.

Different from the disclosure, in the plan view, the third light-emitting layer may overlap the third contact hole. In this case, as the third contact hole is defined, a portion of the circuit layer disposed under the third light-emitting layer may not be flat. Accordingly, the color deviation may occur as the light reflectance of the third light-emitting layer varies. However, according to the disclosure, in the plan view, the third light-emitting layer ELBb may not overlap the third contact hole CNT3b. When the third contact hole CNT3b is defined through the circuit layer 120, the circuit layer 120 disposed under the third light-emitting layer ELBb may be flat. Therefore, the light reflectance of the third light-emitting layer ELBb may be maintained at a constant level, and thus, the color deviation may be prevented. Accordingly, the display quality of the display device DD may be improved.

Different from the disclosure, in the plan view, the third anode may overlap the third data line. In this case, the parasitic capacitance may be generated between the third anode and the third data line, and thus, the load of the data signal applied to the third data line may increase. As a result, the third data line may be insufficiently charged. However, according to the disclosure, the first portion AEB1b and the second portion AEB2b may be spaced apart from each other, and in the plan view, a first space may be defined between the first portion AEB1b and the second portion AEB2b. The second portion AEB2b and the third portion AEB3b may be spaced apart from each other, and in the plan view, a second space may be defined between the second portion AEB2b and the third portion AEB3b. The third data line DL3 may be disposed to overlap the first and second spaces. In the plan view, at least a portion of the third data line DL3 may not overlap the third anode AEBb. The parasitic capacitance generated between the third data line DL3 and the third anode AEBb may be reduced compared to when the third data line DL3 overlaps the third anode AEBb. The increase in the load of the data signal applied to the third data line DL3 due to the parasitic capacitance may be prevented, and thus, the third data line DL3 may be prevented from being insufficiently charged. Therefore, the reliability of the display device DD may be improved.

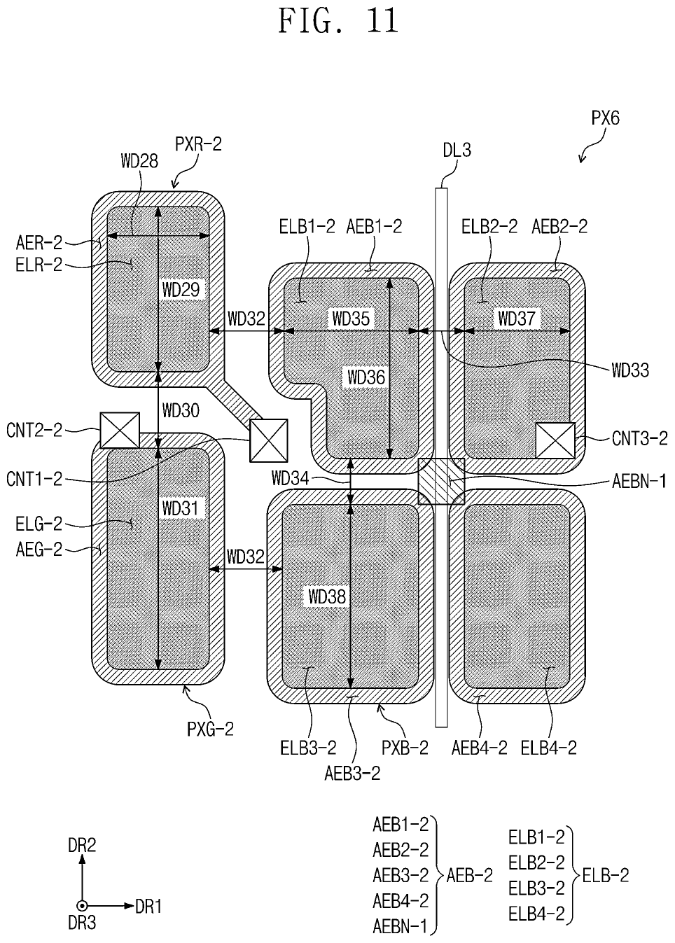

FIG. 11 is a plan view of an embodiment of a portion of a display device according to the disclosure. In FIG. 11, the same reference numerals denote the same elements of FIG. 6, and thus, detailed descriptions of the same elements will be omitted.

Referring to FIGS. 3, 4, 5, and 11, a display panel (refer to DP of FIG. 4) may include a plurality of pixels (refer to PX of FIG. 3). The pixels PX may include a sixth pixel PX6.

The sixth pixel PX6 may include a first sub-pixel PXR-2, a second sub-pixel PXG-2, and a third sub-pixel PXB-2. Each of the first sub-pixel PXR-2, the second sub-pixel PXG-2, and the third sub-pixel PXB-2 may correspond to a sub-pixel (refer to PXSij of FIG. 5).

A light-emitting element ED of the first sub-pixel PXR-2 may be electrically connected to a pixel circuit PXC of the first sub-pixel PXR-2 through a first contact hole CNT1-2. The light-emitting element ED of the first sub-pixel PXR-2 may include a first anode AER-2 and a first light-emitting layer ELR-2. The first anode AER-2 and the first light-emitting layer ELR-2 may be disposed on a light-emitting element layer (refer to 130 of FIG. 4).

The first anode AER-2 may be electrically connected to the pixel circuit PXC of the first sub-pixel PXR-2 through the first contact hole CNT1-2. The first light-emitting layer ELR-2 may be disposed on the first anode AER-2. The first light-emitting layer ELR-2 may emit a red light.

The first light-emitting layer ELR-2 may have a twenty-eighth width WD28 in the first direction DR1. The twenty-eighth width WD28 may be within a range from about 24.50 μm to about 26.50 μm. In an embodiment, the twenty-eighth width WD28 may be about 25.69 μm.

The first light-emitting layer ELR-2 may have a twenty-ninth width WD29 in the second direction DR2. The twenty-ninth width WD29 may be within a range from about 40.50 μm to about 42.50 μm. In an embodiment, the twenty-ninth width WD29 may be about 41.66 μm.

A light-emitting element ED of the second sub-pixel PXG-2 may be electrically connected to a pixel circuit PXC of the second sub-pixel PXG-2 through a second contact hole CNT2-2. The light-emitting element ED of the second sub-pixel PXG-2 may include a second anode AEG-2 and a second light-emitting layer ELG-2. The second anode AEG-2 and the second light-emitting layer ELG-2 may be disposed on the light-emitting element layer 130.

The second anode AEG-2 may be electrically connected to the pixel circuit PXC of the second sub-pixel PXG-2 through the second contact hole CNT2-2. The second light-emitting layer ELG-2 may be disposed on the second anode AEG-2. The second light-emitting layer ELG-2 may emit a green light.

The second light-emitting layer ELG-2 may be spaced apart from the first light-emitting layer ELR-2 by a thirtieth width WD30 in the direction opposite to the second direction DR2. The thirtieth width WD30 may be within a range from about 17.50 μm to about 20.00 μm. In an embodiment, the thirtieth width WD30 may be about 18.47 μm.

The second light-emitting layer ELG-2 may have the same width as the twenty-eighth width WD28 in the first direction DR1. The twenty-eighth width WD28 may be within a range from about 24.50 μm to about 26.50 μm. In an embodiment, the twenty-eighth width WD28 may be about 25.69 μm.

The second light-emitting layer ELG-2 may have a thirty-first width WD31 in the second direction DR2. The thirty-first width WD31 may be within a range from about 54.50 μm to about 56.50 μm. In an embodiment, the thirty-first width WD31 may be about 55.86 μm.

A light-emitting element ED of the third sub-pixel PXB-2 may be electrically connected to a pixel circuit PXC of the third sub-pixel PXB-2 through a third contact hole CNT3-2. In an embodiment, the pixel circuit PXC of the third sub-pixel PXB-2 may be connected to a third anode AEB-2 through one third contact hole CNT3-2. The light-emitting element ED of the third sub-pixel PXB-2 may include a third anode AEB-2 and a third light-emitting layer ELB-2. The third anode AEB-2 and the third light-emitting layer ELB-2 may be disposed on the light-emitting element layer 130.

The third light-emitting layer ELB-2 may be spaced apart from each of the first light-emitting layer ELR-2 and the second light-emitting layer ELG-2 by a thirty-second width WD32 in the first direction DR1. The thirty-second width WD32 may be within a range from about 17.50 μm to about 20.00 μm. In an embodiment, the thirty-second width WD32 may be about 18.47 μm.

The third anode AEB-2 may include a first portion AEB1-2, a second portion AEB2-2, a third portion AEB3-2, a fourth portion AEB4-2, and a connection portion AEBN-1.

The second portion AEB2-2 may be disposed spaced apart from the first portion AEB1-2 in the first direction DR1.

The third portion AEB3-2 may be disposed spaced apart from the first portion AEB1-2 in the direction opposite to the second direction DR2.

The fourth portion AEB4-2 may be disposed spaced apart from the second portion AEB2-2 in the direction opposite to the second direction DR2.

A third data line DL3 may be disposed under the third anode AEB-2. In the plan view, a portion of the third data line DL3 may not overlap the third anode AEB-2.

The connection portion AEBN-1 may electrically connect the first portion AEB1-2, the second portion AEB2-2, the third portion AEB3-2, and the fourth portion AEB4-2 to each other.

The first portion AEB1-2, the second portion AEB2-2, the third portion AEB3-2, the fourth portion AEB4-2, and the connection portion AEBN-1 may be provided integrally with each other.

In the plan view, the second portion AEB2-2 may overlap the third contact hole CNT3-2, and the first portion AEB1-2, the third portion AEB3-2, and the fourth portion AEB4-2 may not overlap the third contact hole CNT3-2.

The third light-emitting layer ELB-2 may be disposed on the third anode AEB-2. The third light-emitting layer ELB-2 may include a first light-emitting portion ELB1-2, a second light-emitting portion ELB2-2, a third light-emitting portion ELB3-2, and a fourth light-emitting portion ELB4-2. The first to fourth light-emitting portions ELB1-2 to ELB4-2 may be disposed on the first to fourth portions AEB1-2 to AEB4-2, respectively.

The first light-emitting portion ELB1-2 may have a shape corresponding to a shape of the first portion AEB1-2, the second light-emitting portion ELB2-2 may have a shape corresponding to a shape of the second portion AEB2-2, the third light-emitting portion ELB3-2 may have a shape corresponding to a shape of the third portion AEB3-2, and the fourth light-emitting portion ELB4-2 may have a shape corresponding to a shape of the fourth portion AEB4-2.

The second light-emitting portion ELB2-2 may be spaced apart from the first light-emitting portion ELB1-2 by a thirty-third width WD33 in the first direction DR1. The thirty-third width WD33 may be within a range from about 10.50 μm to about 12.50 μm. In an embodiment, the thirty-third width WD33 may be about 11.65 μm.

The third light-emitting portion ELB3-2 may be spaced apart from the first light-emitting portion ELB1-2 by a thirty-fourth width WD34 in the direction opposite to the second direction DR2. The thirty-fourth width WD34 may be within a range from about 9.50 μm to about 11.50 μm. In an embodiment, the thirty-fourth width WD34 may be about 10.50 μm.

The first light-emitting portion ELB1-2 may have a thirty-fifth width WD35 in the first direction DR1. The thirty-fifth width WD35 may be within a range from about 32.50 μm to about 34.50 μm. In an embodiment, the thirty-fifth width WD35 may be about 33.82 μm.

The first light-emitting portion ELB1-2 may have a thirty-sixth width WD36 in the second direction DR2. The thirty-sixth width WD36 may be within a range from about 45.50 μm to about 47.50 μm. In an embodiment, the thirty-sixth width WD36 may be about 46.08 μm.

The second light-emitting portion ELB2-2 may have a thirty-seventh width WD37 in the first direction DR1. The thirty-seventh width WD37 may be within a range from about 25.50 μm to about 27.50 μm. In an embodiment, the thirty-seventh width WD37 may be about 26.36 μm.

The second light-emitting portion ELB2-2 may have the same width as the thirty-sixth width WD36 in the second direction DR2.

The third light-emitting portion ELB3-2 may have the same width as the thirty-fifth width WD35 in the first direction DR1.

The third light-emitting portion ELB3-2 may have a thirty-eighth width WD38 in the second direction DR2. The thirty-eighth width WD38 may be within a range from about 44.50 μm to about 46.50 μm. In an embodiment, the thirty-eighth width WD38 may be about 45.09 μm.

The fourth light-emitting portion ELB4-2 may have the same width as the thirty-seventh width WD37 in the first direction DR1.

The fourth light-emitting portion ELB4-2 may have the same width as the thirty-eighth width WD38 in the second direction DR2.

Different from the disclosure, when the first light-emitting portion, the second light-emitting portion, the third light-emitting portion, and the fourth light-emitting portion are provided integrally with each other, the outgas generated from the circuit layer is not discharged, and thus, the lifespan of the third light-emitting layer may be reduced. However, according to the disclosure, there is a gap between the first to fourth light-emitting portions ELB1-2 to ELB4-2, and the outgas generated from a circuit layer (refer to 120 of FIG. 4) may be smoothly discharged. Thus, the pixel shrinkage phenomenon may be reduced, and the lifespan of the third light-emitting layer ELB-2 may increase. Accordingly, the reliability of the display device DD may be improved.

Different from the disclosure, in the plan view, the third light-emitting layer may overlap the third contact hole. In this case, as the third contact hole is defined, a portion of the circuit layer disposed under the third light-emitting layer may not be flat. Accordingly, the color deviation may occur as the light reflectance of the third light-emitting layer varies. However, according to the disclosure, in the plan view, the third light-emitting layer ELB-2 may not overlap the third contact hole CNT3-2. When the third contact hole CNT3-2 is defined through the circuit layer 120, the circuit layer 120 disposed under the third light-emitting layer ELB-2 may be flat. Therefore, the light reflectance of the third light-emitting layer ELB-2 may be maintained at a constant level, and thus, the color deviation may be prevented. Accordingly, the display quality of the display device DD may be improved.

Different from the disclosure, in the plan view, the third anode may overlap the third data line. In this case, the parasitic capacitance may be generated between the third anode and the third data line, and thus, the load of the data signal applied to the third data line may increase. As a result, the third data line may be insufficiently charged. However, according to the disclosure, the first portion AEB1-2 and the second portion AEB2-2 may be spaced apart from each other, and in the plan view, a first space may be defined between the first portion AEB1-2 and the second portion AEB2-2. The third portion AEB3-2 and the fourth portion AEB4-2 may be spaced apart from each other, and in the plan view, a second space may be defined between the third portion AEB3-2 and the fourth portion AEB4-2. The third data line DL3 may be disposed to overlap the first and second spaces. In the plan view, at least a portion of the third data line DL3 may not overlap the third anode AEB-2. The parasitic capacitance generated between the third data line DL3 and the third anode AEB-2 may be reduced compared to when the third data line DL3 overlaps the third anode. The increase in the load of the data signal applied to the third data line DL3 due to the parasitic capacitance may be prevented, and thus, the third data line DL3 may be prevented from being insufficiently charged. Therefore, the reliability of the display device DD may be improved.

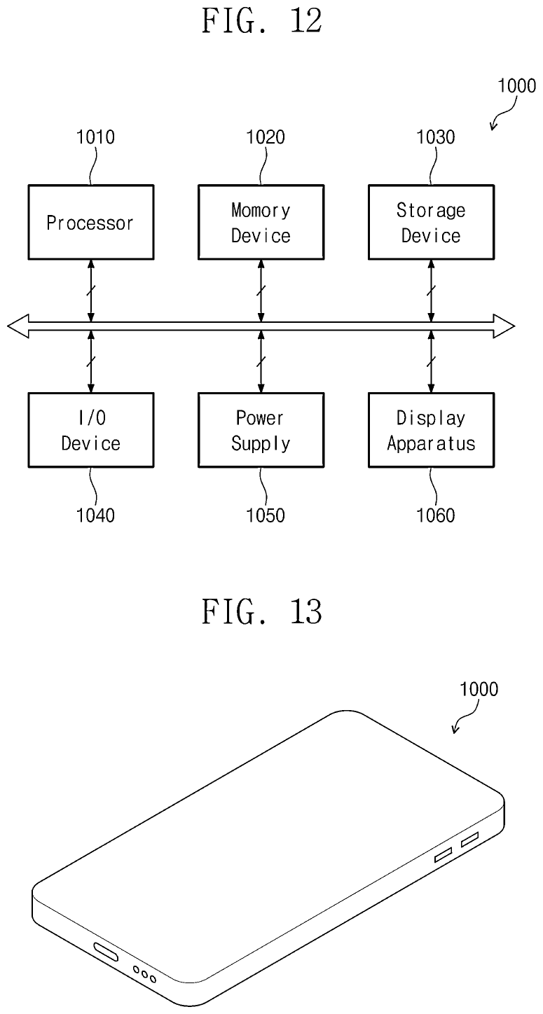

FIG. 12 is a block diagram illustrating an embodiment of an electronic device. FIG. 13 is a view illustrating an embodiment of the electronic device of FIG. 12 implemented as a smartphone.

Referring to FIGS. 12 and 13, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

Although the embodiments of the disclosure have been described, it is understood that the disclosure should not be limited to these embodiments but various changes and modifications may be made by one ordinary skilled in the art within the spirit and scope of the disclosure as hereinafter claimed. Therefore, the disclosed subject matter should not be limited to any single embodiment described herein, and the scope of the inventive concept shall be determined according to the attached claims.

What is claimed is:

1. A display device comprising:
a display panel comprising:
a circuit layer comprising:
a base layer;
a transistor disposed on the base layer;
a connection electrode electrically connecting to the transistor;
a data line disposed on the transistor; and
an insulating layer disposed on the connection electrode and provided with a contact hole defined therethrough, and
a light-emitting element layer disposed on the circuit layer and electrically connected to the transistor through the connection electrode, the light-emitting element layer comprising:
a first electrode disposed on the insulating layer and electrically connected to the connection electrode through the contact hole, the first electrode comprising:
a first portion;
a second portion extending from the first portion to a first direction;
a third portion extending from the first portion to the first direction; and
a fourth portion protruded from one of the first, second, and third portions;
a light-emitting layer disposed on the first electrode; and
a second electrode disposed on the light-emitting layer,
wherein the second portion and the third portion are spaced apart from each other and face each other in a second direction perpendicular to the first direction.

2. The display device of claim 1, wherein the first portion, the second portion, the third portion, and the fourth portion are provided integrally with each other.

3. The display device of claim 1, wherein the data line is disposed between the second portion and the third portion and does not overlap the second portion and third portions in a plan view.

4. The display device of claim 1, wherein the contact hole overlaps the fourth portion in a plan view.

5. The display device of claim 4, wherein the light-emitting layer does not overlap the contact hole in the plan view.

6. The display device of claim 1, wherein the data line overlaps only the first portion in a plan view.

7. The display device of claim 1, wherein the data line is disposed in a same layer as the connection electrode.

8. The display device of claim 1, wherein the light-emitting layer comprises:
a first light-emitting portion having a shape corresponding to a shape of the first portion;
a second light-emitting portion having a shape corresponding to a shape of the second portion; and
a third light-emitting portion having a shape corresponding to a shape of the third portion.

9. The display device of claim 8, wherein the first light-emitting portion, the second light-emitting portion, and the third light-emitting portion are provided integrally with each other.

10. The display device of claim 1, wherein the light-emitting layer emits a blue light.

11. A display device comprising:
a display panel comprising:
a circuit layer comprising:
a transistor;
a connection electrode electrically connected to the transistor; and
an insulating layer disposed on the connection electrode and provided with a contact hole defined therethrough; and
a light-emitting element layer disposed on the circuit layer and electrically connected to the transistor through the connection electrode, the light-emitting element layer comprising:
a first electrode disposed on the insulating layer, the first electrode comprising:
a first portion;
a second portion spaced apart from the first portion by a second width;
a connection portion electrically connecting the first portion and the second portion; and
a protruding portion protruded from one of the first portion, the second portion, and the connection portion;
a light-emitting layer disposed on the first electrode, the light-emitting layer comprising:
a first light-emitting portion; and
a second light-emitting portion spaced apart from the first light-emitting portion by a first width greater than the second width; and
a second electrode disposed on the light-emitting layer.

12. The display device of claim 11, wherein the first electrode further comprises a third portion spaced apart from the second portion in a first direction, and the second portion is spaced apart from the first portion in the first direction.

13. The display device of claim 12, wherein the first portion, the second portion, the third portion, the connection portion, and the protruding portion are provided integrally with each other.

14. The display device of claim 11, wherein the light-emitting layer emits a blue light.

15. The display device of claim 11, wherein the contact hole overlaps the protruding portion in a plan view.

16. The display device of claim 11, wherein the light-emitting layer does not overlap the contact hole in a plan view.

17. The display device of claim 11, wherein the light-emitting layer further comprises a third light-emitting portion spaced apart from the second light-emitting portion by the first width.

18. A display device comprising:
a display panel comprising:
a circuit layer comprising:
a transistor;
a connection electrode electrically connecting the transistor and the light-emitting element layer; and
an insulating layer disposed on the connection electrode and provided with a contact hole defined therethrough; and
a light-emitting element layer disposed on the circuit layer, the light-emitting element layer comprising:
a first electrode disposed on the insulating layer, the first electrode comprising:
a first portion;
a second portion spaced apart from the first portion by a second width; and
a connection portion electrically connecting the first portion and the second portion;
a light-emitting layer disposed on the first electrode, the light-emitting layer comprising:
a first light-emitting portion; and
a second light-emitting portion spaced apart from the first light-emitting portion by a first width greater than the second width; and
a second electrode disposed on the light-emitting layer.

19. The display device of claim 18, wherein the first electrode further comprises a third portion spaced apart from the second portion in a first direction, and the second portion is spaced apart from the first portion in the first direction.

20. The display device of claim 19, wherein the first portion, the second portion, the third portion, and the connection portion are provided integrally with each other.

21. The display device of claim 19, wherein the contact hole overlaps the connection portion in a plan view.

22. The display device of claim 18, wherein the first electrode further comprises:
a third portion spaced apart from the first portion in a first direction; and
a fourth portion spaced apart from the second portion in a second direction intersecting the first direction, and the second portion is spaced apart from the first portion in the second direction.

23. The display device of claim 22, wherein the first portion, the second portion, the third portion, the fourth portion, and the connection portion are provided integrally with each other.

24. The display device of claim 18, wherein the light-emitting layer does not overlap the contact hole in a plan view.

25. The display device of claim 18, wherein the contact hole overlaps the second portion and does not overlap the first portion in a plan view.

26. An electronic device comprising:
A display device comprising:
a display panel comprising:
a circuit layer comprising:
a base layer;
a transistor disposed on the base layer;
a connection electrode electrically connecting to the transistor;
a data line disposed on the transistor; and
an insulating layer disposed on the connection electrode and provided with a contact hole defined therethrough, and
a light-emitting element layer disposed on the circuit layer and electrically connected to the transistor through the connection electrode, the light-emitting element layer comprising:
a first electrode disposed on the insulating layer and electrically connected to the connection electrode through the contact hole, the first electrode comprising:
a first portion;
a second portion extending from the first portion to a first direction;
a third portion extending from the first portion to the first direction; and
a fourth portion protruded from one of the first, second, and third portions;
a light-emitting layer disposed on the first electrode; and
a second electrode disposed on the light-emitting layer,
wherein the second portion and the third portion are spaced apart from each other and face each other in a second direction perpendicular to the first direction.

27. The electronic device of claim 26, wherein the first portion, the second portion, the third portion, and the fourth portion are provided integrally with each other.

28. The electronic device of claim 26, wherein the data line is disposed between the second portion and the third portion and does not overlap the second portion and third portions in a plan view.

29. The electronic device of claim 26, wherein the contact hole overlaps the fourth portion in a plan view.

30. The electronic device of claim 29, wherein the light-emitting layer does not overlap the contact hole in the plan view.

31. The electronic device of claim 26, wherein the data line overlaps only the first portion in a plan view.

32. The electronic device of claim 26, wherein the data line is disposed in a same layer as the connection electrode.

33. The electronic device of claim 26, wherein the light-emitting layer comprises:
a first light-emitting portion having a shape corresponding to a shape of the first portion;
a second light-emitting portion having a shape corresponding to a shape of the second portion; and
a third light-emitting portion having a shape corresponding to a shape of the third portion.
